(19) United States
(12) Patent Application Publication
(10) Pub. No.: US 2012/0181973 A1
(43) Pub. Date: Jul. 19, 2012

(54) SOLAR ARRAY RESEMBLING NATURAL FOLIAGE INCLUDING MEANS FOR WIRELESS TRANSMISSION OF ELECTRIC POWER

(76) Inventor: Robert Lyden, Aloha, OR (US)

(21) Appl. No.: 13/230,764

(22) Filed: Sep. 12, 2011

Related U.S. Application Data
(63) Continuation-in-part of application No. 13/027,207, filed on Feb. 14, 2011.
Application No. 13/027,207 is a continuation of application No. 10/652,474, filed on Aug. 29, 2003, now Pat. No. 7,888,584.

(51) Int. Cl. H02J 7/00; H01L 31/042

(52) U.S. Cl. 320/101; 136/244

(57) ABSTRACT

The present invention teaches a solar array, and also a network of solar arrays for providing energy for industrial, residential and transportation use. A solar array of the present invention can be made to resemble a palm tree, a deciduous tree, an evergreen tree, or other type of natural foliage, and meet the aesthetic demands of landscape architecture. A network of solar arrays can extend for many miles along transportation right of ways including, but not limited to, roads, highways, railways, pipelines, or canals, and can further include means for storing and transmitting energy. A solar array can include or be coupled with a recharging station for use by electric and hybrid transportation vehicles. Moreover, an individual solar array or network of solar arrays can include means for wireless communication and transmission of energy for recharging an energy storage device and provide energy to an electric or hybrid transportation vehicle.

### CLAIM OF PRIORITY

The present invention is a Continuation-In-Part and claims priority to U.S. patent application Ser. No. 13/027,207, filed Feb. 14, 2011, which is a Continuation of U.S. patent application Ser. No. 10/652,474, filed on Aug. 29, 2003, and which issued as U.S. Pat. No. 7,888,584 on Feb. 15, 2011, the complete contents of which are hereby incorporated by reference.

### BACKGROUND

1. Field of the Invention

The present invention relates to a solar cell, a solar module, a solar array, a network of solar arrays, and a solar power grid for generating electric power for industrial, residential, and transportation use, and including means for wireless communication and transmission of electrical power.

2. Background

The world's present population is over six billion, and it is projected that by the year 2020 it will grow to over nine billion persons. Worldwide power consumption in 1997 was approximately 380 quadrillion British thermal units (Btu), and in response to the projected growth in population and industry the demand for power is expected to grow to about 608 quadrillion Btu by the year 2020. Likewise, worldwide consumption of oil is presently over 75 million barrels per day, and demand is expected to grow to about 120 million barrel per day by the year 2020. The world's oil reserves are estimated to be approximately 1,027 billion barrels. Fossil fuels such as coal, gas, and oil are non-renewable resources, and the burning of these fuels results in pollution of the earth's atmosphere, land, and water. Further, the burning of various fossil fuels contributes to global warming and dramatic changes in climate, thus mankind is presently faced with an environmental catastrophe. Various alternate means of producing power such as hydrogen cells are presently being developed for use. However, even the burning of a non-fossil fuel such as hydrogen can possibly contribute to the problem of global warming. The United States and other industrialized nations of the world are still largely dependent upon internal combustion engines for transportation which consume gasoline or diesel fuel. Accordingly, the demand for a renewable and environmentally friendly source of power is one of the foremost needs and problems facing mankind.

Moreover, the creation of power generating facilities have sometimes compromised aesthetics and had other adverse environmental impacts. Dams have sometimes restricted the navigation of waterways and adversely affected fish populations such as salmon in the Pacific Northwest region of the United States. Nuclear power stations have been associated with radiation leaks, pollution, and the production of hazardous radioactive waste, whereas coal, oil and gas burning power stations are associated with more conventional forms of pollution. The installation of poles including overhead transmission lines alongside roads can sometimes constitute a hazard for motorists and compromise aesthetics.

Substantially all of the energy required for the creation and maintenance of life on the earth was originally provided by the sun. Solar energy is renewable and environmentally friendly. Faced with population, energy, and pollution crises, mankind can take a lesson from nature. The evolution of trees and other natural foliage on earth has been such as to maximize their ability to collect sunlight and perform photosynthesis. The present invention is directed towards providing renewable solar energy using solar arrays which resemble and emulate some of the light gathering abilities of natural foliage. In the words of Thomas Aquinas, “Grace does not abolish nature but perfects it.”

One of the present challenges and unanswered questions in the field of solar energy concerns how to make solar arrays that can provide environmentally green electrical energy and power comprising a structure which is aesthetically pleasing so as to be desirable for installation in close proximity to residential homes, businesses, parking areas, but also alongside streets, and highways. In this regard, solar arrays resembling palm trees which can provide electrical energy, and further comprise wireless transmission devices for the recharging and powering electrical devices including electric and hybrid transportation vehicles can provide a viable solution.

It is clear that United States needs to switch from automobiles which burn gasoline and diesel fuel to electric and hybrid vehicles as soon as possible. In this regard, it should be recognized that merely switching from automobiles that burn gasoline and diesel fuel to electric and hybrid vehicles which must be charged by electric power plants that burn fossil fuels would not provide a viable long term solution to the world's energy and pollution problems. At this time, and for the foreseeable future, the only clean and renewable form of electric power comes from the sun. That energy and power needs to be made available in and alongside our nation's public transportation right of ways including railways, roads and highways. Accordingly, the creation of a network of solar arrays and along roads and highways will not only provide electrical energy and power for residential and commercial use, but also support the widespread use of electric and hybrid transportation vehicles.

### SUMMARY OF THE INVENTION

The present invention teaches a solar cell, a solar module, a solar array, a network of solar arrays, and also a solar power grid suitable for providing power for industrial, residential and transportation use. A solar cell or solar module including a plurality of solar cells can be made in a structure configured to have the appearance of natural foliage. Accordingly, a solar array including a plurality of solar modules each including at least one solar cell can be made to resemble a tree, including, but not limited to, a palm tree, a deciduous tree, or an evergreen tree. Further, a network of solar arrays can be made to resemble a row or grove of palm trees and meet the functional and aesthetic demands of landscape architecture. In this regard, a network of solar arrays comprising a structure configured to resemble natural foliage can comprise a portion of the landscape architecture about a residential home, business, government building, or other public place. In addition, a solar array or network of solar arrays can be included in parking areas, lots, and also parking structures. Moreover, a network of solar arrays can extend for many miles in or alongside public right of ways, and in particular, public transportation right of ways including, but not limited to paths, roads, streets, highways, railways, pipelines, or canals.

A solar array can include or be coupled to at least one energy storage device for storing, and also transmitting devices for transmitting energy, including, but not limited to, electrical energy and power. In particular, a solar array can include or be coupled in functional relation with at least one recharging station for use by electric and hybrid transportation vehicles. The recharging station can include mechanical means for making a direct connection with a transportation vehicle, including, but not limited to, an electric cord, or a conduit for the transmission of solid or fluid matter, and the like. Further, a recharging station can provide one or more fully recharged energy storage devices, including, but not limited to, electric batteries or capacitors, for making a rapid exchange with one or more energy storage devices present on a transportation vehicle which are substantially depleted. In addition, a recharging station can include wireless means for transmitting energy such as a wireless transmission device which can be coupled with a remote wireless receiver device. Moreover, a wireless transmission device can be capable of being coupled in functional relation to a wireless repeater device for extending the range of transmission of energy to an electrical device, including, but not limited to, an electrical appliance, and an electric or hybrid transportation vehicle.

The present invention teaches a solar cell comprising a structure configured to resemble natural foliage. The solar cell can comprise a structure configured to resemble a leaf. Alternatively, the solar cell can comprise a structure configured to resemble a branch including at least one leaf. Moreover, a solar cell can comprise a structure configured to resemble a branch or leaf comprising a palm frond. A solar cell comprising a structure configured to resemble natural foliage can further include means for integral energy storage, including, but not limited to an energy storage device such as a battery, or capacitor.

The present invention teaches a solar module including a plurality of solar cells comprising a structure configured to resemble natural foliage. The solar module including a plurality of solar cells comprising a structure configured to resemble natural foliage can comprise a leaf. Further, the solar module including a plurality of solar cells comprising a structure configured to resemble natural foliage can comprise a branch including at least one leaf. The solar module including a plurality of solar cells comprising a structure configured to resemble natural foliage can comprise a palm frond.

The present invention teaches a solar array comprising a structure configured to resemble natural foliage. The solar array can comprise a structure configured to resemble a plant such as a fern, a bush, grass, or other plant variety or species. In particular, a solar array can comprise a structure configured to resemble natural foliage comprising a tree, such as a palm tree, a deciduous tree, or an evergreen tree. In this regard, the solar array comprising a structure configured to resemble natural foliage can comprise a plurality of solar modules each including at least one solar cell.

The solar array comprising a structure configured to resemble natural foliage can further comprise means for storing electrical energy and power including, but not limited to, an energy storage device such as a battery or capacitor. A solar array comprising a structure configured to resemble natural foliage can further comprise: an inverter for changing DC current to AC current; a converter for changing AC current to DC current; and, a transformer for changing the voltage of electric current. In this regard, a transformer can comprise a step-up transformer for increasing the voltage of electric current, or alternatively can comprise a step-down transformer for decreasing the voltage of electric current.

A solar array comprising a structure configured to resemble natural foliage can further comprise means for transmitting energy such as a wire or fiber optic transmission line, or a wireless transmission device. The solar array comprising a structure configured to resemble natural foliage can further comprise means for recharging electric appliances such as a wireless recharging device. A solar array comprising a structure configured to resemble natural foliage can further comprise means for recharging a transportation vehicle, and such can comprise a battery or capacitor recharging device for a transportation vehicle. The solar array comprising a structure configured to resemble natural foliage can further comprise wireless means for recharging a transportation vehicle such as a wireless transmission device which may be coupled with a remote wireless receiver device.

A solar array can be configured to resemble a tree selected from the group of trees consisting of deciduous trees, evergreen trees, and palm trees. The trunk portion of the solar array can comprise a support pole and an interior compartment. Each of the solar modules can be configured to resemble a palm frond including a stem portion and a blade portion. The stem portion can extend from the trunk portion, and the blade portion can include at least one solar cell having a working surface area for capturing sunlight and for providing an electrical energy output. Wiring can be coupled to the plurality of solar modules for conducting electrical energy output. And at least one mechanical fastener can be used for securing the solar array in an upright position. The solar modules and solar array can have a green coloration.

The solar array can include wiring extending to a wireless transmission device for wireless communication of electrical energy to a transportation vehicle including a compatible wireless receiver device. The wireless transmission device can be substantially planar and located on a substantially horizontal surface capable of supporting a transportation vehicle. The wireless receiver device can be generally planar and located on a lower surface of the transportation vehicle. Alternatively, the wireless transmission device can be located on a vertical support surface of the solar array. Alternatively, the wireless transmission device can be located on a curb. Alternatively, the wireless receiver device can be located on at least one of the front, rear, and side surfaces of the transportation vehicle. The wireless transmission device can be electrically coupled with at least one repeater device adapted to extend the range of wireless communication and transmission of electric power.

The solar array can include wired communication with a monitoring and controlling device having a visual display. Alternatively, the solar array can include wireless communication with a monitoring and controlling device having a visual display. The monitoring and controlling device can comprise an electronic device selected from the group of electronic devices consisting of monitors, controllers, computers and cell phones. The solar array can provide an electrical energy output and be electrically coupled with an electrical energy storage device such as a battery or capacitor for storing the electrical energy.

The solar array can comprise at least one electronic component selected from the group of electronic components consisting of adaptors, AC disconnects, amplifiers, batteries, battery cables, battery controllers, battery status meters, bias voltage supply devices, breakers, capacitors, central processing units, chips, circuit breakers, coils, tesla coils, computers, conduits, connectors, controllers, charge controllers, micro-controllers, control panels, digital and panel controls, converters, combiners, DC disconnects, DC-DC power optimizers, diodes, drivers, gate drivers, full bridge drivers, extension cords, filters, fuses, generators, grid tie power centers, ground fault switches, h-bridge power stages, inductors, integrated circuits, inverters, micro-inverters, junction boxes, lights, meters, metal oxide semiconductors, output current and voltage sense amplifiers, off grid power centers, power supplies, power optimizer chipsets switching power supplies, quasi-resonant flyback devices, rectified full wave Sine-to-Sine bridges, regulators, RF receivers, repeaters, resistors, sensors, sensing and detection devices, software, shot reactors, static var compensators, surge protectors, switches, temperature sensors, thyristors, transformers, transistors, bi-polar junction transistors, voltage regulators, wiring, wireless RF communication devices, wireless transmitters, wireless receivers, and wireless repeaters.

The solar array electrically coupled with a wireless transmission device can be combined with at least one additional like solar array to form a network of solar arrays. Further, the network of solar arrays can be coupled to an electric power grid. In addition, the network of solar arrays can be coupled to at least one recharging station adapted to provide electrical energy to the electric power storage device of a transportation vehicle. The recharging station can include means for wireless transmission of electric power such as a wireless transmission device, and also a wireless repeater device.

The wireless transmission device adapted to transmit power can transmit energy comprising a portion of the electromagnetic spectrum. The energy comprising a portion of the electromagnetic spectrum can consist of energy selected from the group of gamma ray energy, x-ray energy, ultraviolet light energy, visible light energy, infrared energy, microwave energy, radio frequency energy, radar energy, electrical energy, television signal energy, and telephone signal energy. The means for wireless communication and transmission of electric power can comprise electromagnetic radiation. The means for wireless communication and transmission of electric power can comprise electromagnetic inductance. Alternatively, the means for wireless communication and transmission of electric energy can comprise radio frequency energy.

The solar array which is electrically coupled with a wireless transmission device can be located in a parking area for recharging an electric power storage device of a transportation vehicle. Further, the network of solar arrays can be located in or alongside a transportation right of way, and the path of travel of one or more transportation vehicles, and be adapted for wireless transmission of electrical energy to the energy storage and power devices of transportation vehicles while they are in motion.

A solar array resembling natural foliage of the present invention can include an antenna. Further, a solar array resembling natural foliage of the present invention can include a communication device selected from the group of communication devices consisting of antennas, receivers, transmitters, relays, and repeaters. In addition, a solar array resembling natural foliage of the present invention can include an electrolyser device adapted to provide hydrogen fuel. Moreover, a solar array resembling natural foliage of the present invention can include an electrolyser device adapted to provide pure water.

### BRIEF DESCRIPTION OF THE DRAWINGS

FIG. 1 is a perspective side view of an artificial palm tree that consists of a solar array.

FIG. 2 is a top plan view of an artificial palm frond that consists of a solar module including at least one solar cell for use with an artificial palm tree that consists of a solar array.

FIG. 3 is a top plan view an alternate artificial palm frond that consists of a solar module including a plurality of solar cells for use with an artificial palm tree that consists of a solar array.

FIG. 4 is a top plan view an alternate artificial palm frond including a plurality of blades that consists of a solar module including a plurality of solar cells for use with an artificial palm tree that consists of a solar array.

FIG. 5 is a side cross-sectional view of an alternate solar module including a solar cell having a textured surface including a plurality of peaks and valleys.

FIG. 6 is a side cross-sectional view of an alternate solar module including a solar cell including an integral capacitor.

FIG. 7 is a top plan view of one layer of artificial palm fronds, each artificial palm frond consisting of a solar module including at least one solar cell for use with an artificial palm tree that consists of a solar array.

FIG. 8 is a top plan view of two staggered layers of artificial palm fronds, each artificial palm frond consisting of a solar module including at least one solar cell for use with an artificial palm tree that consists of a solar array.

FIG. 9 is a perspective side view of an artificial palm tree that consists of a solar array showing one possible orientation of five layers of artificial palm fronds, each artificial palm frond consisting of a solar module including at least one solar cell.

FIG. 10 is a side cross-sectional view of a top portion of a trunk of an artificial palm tree that consists of a solar array including provision for four layers, and also a cap portion showing both internal and external components.

FIG. 11 is a side cross-sectional view of an alternate top portion of an artificial palm tree including provision for two layers showing both internal and external components.

FIG. 12 is a side cross-sectional view of an alternate top portion of an artificial palm tree including provision for one layer showing both internal and external components.

FIG. 13 is a side view with parts broken away of an alternate middle portion of a trunk of an artificial palm tree including at least two sections which can be removably secured together to substantially determine the overall height of an artificial palm tree.

FIG. 14 is a side cross-sectional view of an alternate top portion and cap portion of a trunk of an artificial palm tree for accommodating a transformer.

FIG. 15 is a side cross-sectional view of a bottom portion of a trunk and also a footing of an artificial palm tree that consists of a solar array.

FIG. 16 is a side cross-sectional view of a bottom portion of a trunk of an artificial palm tree generally similar to that shown in FIG. 15, but including additional electrical devices within the interior compartment.

FIG. 17 is a top perspective view of an alternate access door to the interior compartment of the bottom portion of the trunk of an artificial palm tree.

FIG. 18 is a side perspective view of a solar electric power control panel for possible residential use.

FIG. 19 is a perspective view of one side of a street and sidewalk including a row of artificial palm trees that consist of solar arrays.

FIG. 20 is a perspective view of two rows of artificial palm trees that consist of solar arrays positioned on opposite sides of a street.

FIG. 21 is a top plan view of a section of interstate highway showing a plurality of artificial palm trees that consist of solar arrays.

FIG. 22 is a side perspective view of an electric or hybrid automobile parked at an electric recharging station by the side of a road.

FIG. 23 is a top view of an artificial oak leaf for use with an artificial deciduous oak tree that consists of a solar array.

FIG. 24 is a top view of an artificial maple leaf for use with an artificial deciduous maple tree that consists of a solar array.

FIG. 25 is a side perspective view of an artificial deciduous maple tree that consists of a solar array.

FIG. 26 is a top view of a portion of an artificial evergreen tree branch and leaf for use with an artificial evergreen tree that consists of a solar array.

FIG. 27 is a side perspective view of an artificial evergreen tree that consists of a solar array.

FIG. 28 is a top view of an artificial fern leaf for making an artificial fern plant consisting of a solar array.

FIG. 29 is a side perspective view of an artificial palm tree that consists of a solar array including a plurality of artificial palm fronds that consist of solar modules.

FIG. 30 is a flow diagram showing a solar array in communication with a grid-tie DC to AC inverter that is in communication with low voltage AC power transmission lines associated with an AC power grid.

FIG. 31 is a flow diagram showing a solar array in communication with low voltage DC power transmission lines associated with a DC solar power grid.

FIG. 32 is a top plan view of an artificial palm frond including a stem portion and also a blade portion having smooth edges.

FIG. 33 is a top perspective view of a transportation vehicle connected with the use of hard wiring and in this case a recharging cord to a solar array having an integral recharging station including a vending machine device.

FIG. 34 is a side view illustration with some parts broken away of a transportation vehicle including a wireless receiver device on a lower surface positioned over a wireless transmission device which is located on the underlying support surface and electrically coupled to a solar array resembling a palm tree.

FIG. 35 is a side view illustration with some parts broken away of a transportation vehicle including a wireless receiver device on a front surface positioned adjacent to a wireless transmission device positioned on a curb which is electrically coupled to a solar array resembling a palm tree.

FIG. 36 is a side perspective view showing a plurality of wireless repeater devices located on a horizontal support surface in a parking lot having individual parking spaces indicated by lines.

FIG. 37 is a top plan view showing a network of solar arrays resembling palm trees including means for wireless communication and transmission of electric power such as wireless transmission devices located alongside both sides a street, and also a transportation vehicle in motion.

FIG. 38 is a top plan view similar to FIG. 37 showing a network of solar arrays resembling palm trees including means for wireless communication and transmission of electric power such as wireless transmission devices located alongside both sides of a street, but also a plurality of wireless repeater devices.

FIG. 39 is a top plan view showing a network of solar arrays resembling palm trees including means for wireless communication and transmission of electric power such as wireless transmission devices located alongside a highway and electrically coupled with a plurality of wireless repeater devices on a centerline barrier and divider, but also the use of at least one electrolyser device.

FIG. 40 is a side view of a solar array resembling a palm tree with parts broken away to show the inclusion of an antenna.

FIG. 41 is a side view of a solar array resembling a palm tree with parts broken away to show the inclusion of a plurality of cell antennas.

### DETAILED DESCRIPTION

The present invention teaches a solar cell, a solar module, a solar array, a network of solar arrays, and also a solar power grid suitable for providing power for industrial, residential and transportation use. A solar cell or solar module including a plurality of solar cells can be made in a structure configured to have the appearance of natural foliage. Accordingly, a solar array including a plurality of solar modules each including at least one solar cell can be made to resemble a tree, including, but not limited to, a palm tree, a deciduous tree, or an evergreen tree. In this regard, a network of solar arrays can be made to resemble a row or grove of palm trees, and then meet both the functional and aesthetic demands of landscape architecture.

### Palm Trees

Palm trees line the streets of Beverly Hills, Calif., but also Las Palmas Drive in Hope Ranch, and also along the beach in Santa Barbara, Calif., a location that is sometimes called the American Riviera. Similarly, palm trees line the street and beach area in the city of Bandol, France and much of the French Riviera. Further, the presence of palm trees has long been associated with the presence of an oasis, water, life, and wealth in the Middle East. Accordingly, palm trees line most of the major streets and highways in the United Arab Emirates. In contrast with conventional power and telephone poles associated with overhead transmission lines, a palm tree, even an artificial palm tree, has an appearance which is aesthetically pleasing and associated with an well to do neighborhood and community.

A multitude of different palm tree species exist having different characteristics. Common varieties of palm trees include date palms, banana palms, coconut palms, queen palms, and royal palms. Palm trees having upwards of six and even thirty or more leaves or palm fronds are common. Trees are one of nature's solar collectors. The palm tree often includes a multiplicity of palm fronds projecting at a plurality of different angles and orientations relative to the truck of the palm tree in order to maximize its ability to capture light. The resulting exposed surface area can be substantial, and in this regard nature has provided an efficient model for capturing sunlight from sunrise to sunset. Further, when the ground surface surrounding a tree such as a palm tree consists of light colored sand or other surface that reflects substantial light, the tree's leaves or palm fronds can capture reflected light as well as direct sunlight. Accordingly, light can sometimes be captured by the bottom side of the leaves or palm fronts as well as the top side. This greatly increases the exposed surface area and enhances the ability of the foliage to capture light.

### Artificial Palm Tree Manufacturers

Manufacturers of artificial palm trees in the United States which are suitable or may be readily adapted for use in the present invention having a realistic appearance include Tropical Expressions of 2127 Bride Ave., Point Pleasant, N.J. 08742, having a website: http://tropicalexpressions.com as of Jun. 7, 2011, and phone (732) 899-1733; Tropical Palm Tress of 3950 N. 20^{th} Street, Ozark, Mo. 65721, having a website: http://www.tropicalpalmtrees.com as of Jun. 7, 2011, and phone (417) 581-1048; Custom Made Palm Tree Company of 1201 DeValera Street, Akron, Ohio 44310, having a website: http://www.custompalmtrees.com as of Jun. 7, 2011, and phone (866) 349-4582; Earthfflora.com of 1099 Bradley Road, Westlake, Ohio 44145, having a website: http://www.earthflora.com as of Jun. 7, 2011, and phone (877) 252-1675; Oasis Illusions of 419 Mullica Hill Road, Richwood, N.J. 08074, having a website: http://www.oasisillusions.com as of Jun. 7, 2011, and phone ((856) 582-9422; Xtremely Tropical of 11428 Moog Drive, St. Louis, Mo. 63146, having a website: http://xtremelytropical.com as of Jun. 7, 2011, and phone (314) 785-1700; Artificial Plants and Trees of 51 Glen Street, Natick, Mass. 01760, having a website: http://artificalplantsandtrees.com as of Aug. 29, 2011, and phone (888) 532-0232.

### Antenna Towers Disguised as Trees

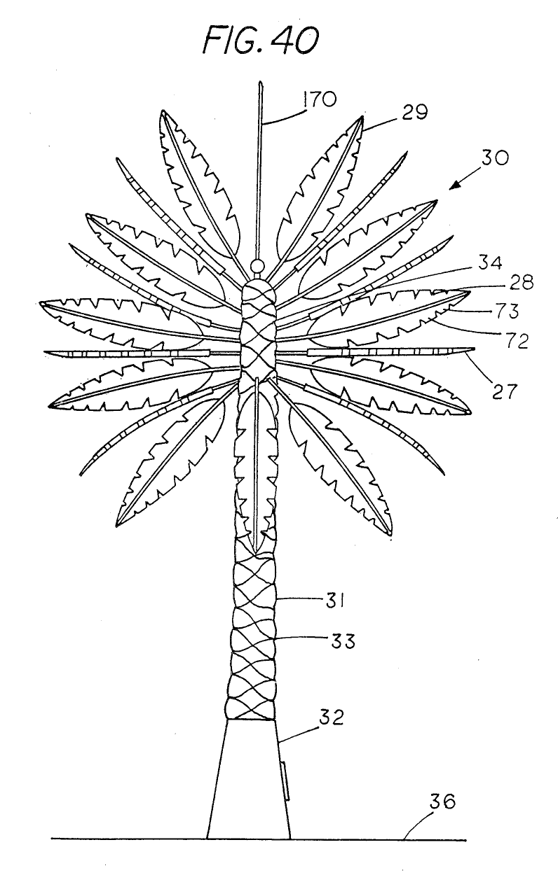

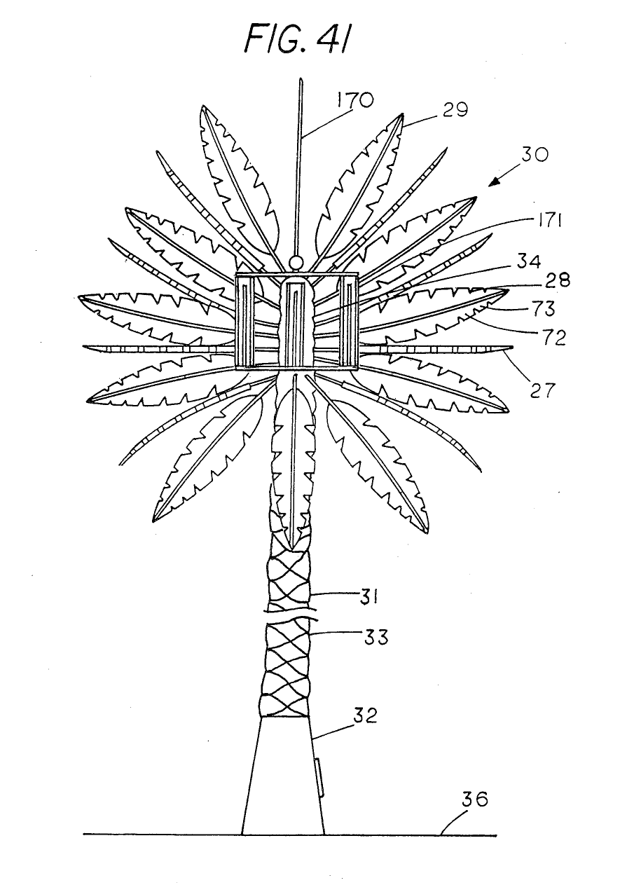

Antenna towers which are disguised to have the appearance as trees are taught in U.S. Pat. No. 5,611,176, U.S. Pat. No. 5,787,649, U.S. Pat. No. 6,343,440, and U.S. 2002/0184833, the complete contents of all of these patents and the patent application hereby being incorporated by reference herein. For example, the Custom Made PalmTree Company of Akron, Ohio presently makes and sells artificial palm trees for concealing cell towers which can be adapted for use in the present invention. Moreover, as shown and discussed in greater detail below in FIGS. 40 and 41, the present application teaches a solar array 30 which can provide energy for an antenna 170 and cell tower devices 171.

### Solar Arrays Resembling Trees

Conventional solar cells are commonly made in standard geometric shapes such as squares, rectangles, or circles. However, the present invention teaches making solar cells and solar modules including at least one solar cell having the appearance of leafs, palm fronds, branches, plants, trees and other natural foliage. Further, the present invention teaches making solar cells and solar modules in colors to resemble natural foliage. For example, plastic solar cell thin films and solar cells made by painting or other coating process can be pigmented to assume a desired color, and this can include the primary colors red, yellow, blue, and green, as well as a multiplicity of other colors, shades, and tones. Moreover, instead of the individual solar cells in a solar module being square, rectangular, or circular in appearance, the present invention teaches solar cells having a structure configured to resemble that of natural foliage, and in particular, the structures found in various types of leaves which commonly include a plurality of veins and isolated groups of plant cells. As a result, artificial leaves, palm fronds, branches, plants, and trees, as well as other artificial foliage can be created which closely resemble their natural counterparts. Besides providing clean and renewable solar generated electric power, the artificial foliage can provide shade, serve as windbreak, and meet both the functional and aesthetic demands of landscape architecture. Several non- limiting embodiments of solar arrays resembling natural foliage, and including certain solar arrays configured to resemble palm trees are discussed in greater detail below.

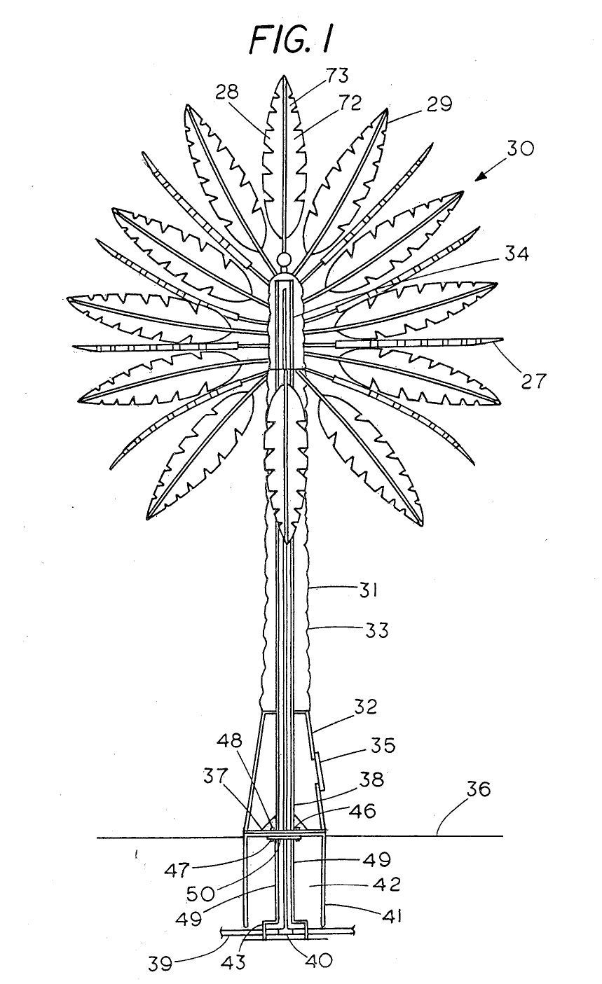

FIG. 1 is a side perspective view of an artificial palm tree 29 that constitutes a solar array 30. The artificial palm tree 29 and solar array 30 can include a trunk 31 having a trunk bottom portion 32, a trunk middle portion 33, and trunk top portion 34. The truck bottom portion 32 can include an access door 35. The artificial palm tree 29 and solar array 30 can include a central support pole 38 including a base 37 having a reinforced base flange 46. The base flange 46 can bear against a footing 126 including support platform 49 having a reinforced platform flange 50. The support platform 49 can include a bottom portion including a stand-off 43 for permitting concrete to substantially encompass the support platform 49. The concrete can be contained when poured by a circular shaped tube or form 41. The top side of the platform flange 50 of the support platform 49 can then be made approximately level with the surrounding ground surface 36. The base flange 46 can be secured to the platform flange 50 using bolts 47, nuts 48, and washers 51 which can also be used to properly align the central support pole 38 vertically. The artificial palm tree 29 and solar array 30 can include a plurality of artificial palm fronds 72 that include at least one solar panel or solar module 28 including at least one solar cell 73. The artificial palm tree 29 and solar array 30 can include at least one layer 27 of artificial palm fronds 72, and each layer can include a plurality of artificial palm fronds 72 and solar modules 28. Alternatively, the structure and placement of the artificial palm fronds 72 and solar modules 28 can be configured to appear more random. The artificial palm tree 29 and solar array 30 can include a plurality of artificial palm fronds 72 that include at least one solar panel or solar module 28 including at least one solar cell 73. The solar cell 73 can be a photovoltaic solar cell comprising a monocrystalline, polycrystalline, or amorphous structure, or any other known structure. In this regard, a more detailed disclosure and discussion of solar cells and solar modules which can be suitable for use in making a solar array 30 of the present invention is provided below.

### Solar Cells and Solar Modules

Photovoltaic solar cells having a monocrystalline, polycrystalline, or amorphous structure, and an efficiency in the range between 1-35 percent have been in use for some time, and the associated cost of electricity using this technology has been in the range between 20-30 cents per kilowatt-hour, as compared with 9-10 cents for hydroelectric generated power. However, the efficiency of photovoltaic solar cells continues to improve, and their costs continue to decline such that they are expected to be as cost-effective as other forms of power within the next decade.

Most commercial solar cells and modules on the market today are made from rigid crystalline silicon wafers that are about 150 um thick, and these products are relatively expensive to manufacture. These products can be made of a homogenous crystalline silicone material, or multicrystaline silicone materials, and may include silicone heterostructures. An example of a manufacturer which makes monocrystalline and polycrystalline solar panels is SolarWorld AG, which has a subsidiary in the United States located at 25300 N.W. Evergreen Road, Hillsboro, Oreg. 97124, (503) 844-3400, and a website: www.solar-world-usa.com as of Aug. 29, 2010.

Alternatively, the amorphous thin-film materials demonstrate efficiencies between 4-13% and the equipment required to make the material are well known. Manufacturers of amorphous thin-film materials include but are not limited to the following companies: PowerFilm, Inc. of 2337 230^{th} Street, Ames, Iowa 50014, (888) 354-7773, having a website: www.powerfilmsolar.com as of Feb. 1, 2011, which makes a flexible thin film photovoltaic material based on amorphous silicon; Solarmer Energy, Inc. of 3445 Fletcher Avenue, El Monte, Calif. 91731, (626) 456-8082, having a website: www.solarmer.com as of Aug. 29, 2011, which makes transparent flexible thin film photovoltaic materials which can also be printed in multiple colors and on fabrics; and, Uni-Solar, that is, United Solar Ovonic, LLC. of 3800 Lapeer Road, Auburn Hills, Mich. 48326, (248) 293-0440, having a website: www.uni-solar.com as of Aug. 29, 2011, which makes several different types of both rigid and flexible solar products including “PowerBond,” “PowerTilt,” “EnerGen,” and “PowerShingle.”

In addition, three types of thin-film solar cells and modules have been developed with may utilize only a 1-4 um thick layer of semiconductor material and these are either based on amorphous silicon, cadmium telluride (CdTe), or copper-indium-gallium-selenide (CIGS). The cadmium telluride (CdTe) materials can achieve an efficiency of 16.5% and their manufacturing costs are low, but they are limited to application on rigid glass substrates. Manufacturers of cadmium telluride (CdTe) materials include but are not limited to the following companies: First Solar, Inc. of 350 West Washington Street, Suite 600, Tempe, Ariz. 85281, (419) 662-6899, having a website: www.firstsolar.com as of Feb. 1, 2011, which makes thin film photovoltaic modules on glass using cadmium telluride (CdTe) as a semiconductor instead of the more common crystalline silicon; and, Solexant, Corp. of 2329 Zanker Rd., San Jose, Calif. 95131, (408) 240-8900, having a website: www.solexant.com as of Aug. 29, 2011, which makes a nanocrystal ultrathin-film solar material using a roll to roll technique which will first use CdTe based nanocrystals, and they expect to use other nanocrystal materials within the next five years.

The copper-indium-gallium-selenide (CIGS) materials can achieve an efficiency of 19.9% and they can be applied on glass or flexible substrates, and have been relatively expensive to produce. Manufacturers of copper-indium-gallium-selenide (CIGS) materials include but are not limited to the following companies: Ascent Solar Technologies, Inc. of 12300 N. Grant Street, Thorton, Colo. 80241, (720) 872-5000, having a website: www.ascentsolar.com as of Aug. 29, 2011, which makes flexible thin film solar modules using copper indium galliaum (di)selenide (CIGS) that has shown a 19.5% efficiency in real world conditions; SoloPower of 5981 Optical Court, San Jose, Calif. 95138, (408) 281-1582, having a website: www.solopower.com as of Aug. 29, 2011, which makes CIGS based photovoltaic materials using a proprietary electrochemical process in a roll to roll manufacturing process; Global Solar of 8500 South Rita Road, Tuscon, Ariz. 85747, (520) 546-6318, having a website: www.globalsolar.com as of Aug. 29, 2011, which make a PowerFLEX thin film roll product having dimensions of 5.74 meters by 0.49 meters and an efficiency in the range between 10.5-12.6% which sells for approximately $875., thus a cost of approximately $2.50 per watt; and, Nanosolar, Inc. 5521 Hellyer Avenue, San Jose, Calif. 95138, (408) 365-5960, having a website: www.nanosolar.com as of Aug. 29, 2011, which makes a CIGS material printed on conductive metal foil using deposition processes developed for continuous steady-state processing within a roll-to-roll manufacturing.

Emerging types of photovoltaic materials include organic, inorganic and dye-sensitive solar cells. Manufacturers of organic solar cells include but are not limited to the following companies: Heliatek GmbH, of Treidlerstrasse 3, D-01139, Dresden, Germany, (49) 35121303430, having a website: www.heliatek.com as of Aug. 29, 2011, which makes organic photovoltaics (OPV) by vacuum depositing small molecule organic photovoltaics which has achieved an efficiency of 8.3%. An alternative manufacturing technology is to wet-print the organic material. The company can make a proprietary tandem cell construction. Another manufacturer of organic solar cells is Konarka Technologies, Inc. of 116 John Street, Suite 12, Lowell, Mass. 01852, (978) 569-1400, having a website: www.konarka.com as of Aug. 29, 2011, which makes flexible organic thin film photovoltaic material using a roll to roll printing process. The company has the ability to make green colored and also multi-colored photovoltaic material. Further, the company is making a transparent photovoltaic material which can be inserted into windows.

Manufacturers of dye-sensitive solar cells include but are not limited to the following companies: Dyesol of 3 Dominion Place, Queanbeyan, NSW, 2620, Australia (61) 2 6299 1592, having a website: www.dyesol.com as of Aug. 29, 2011, which makes dye-sensitive solar cells (DSSC or DSC) including ruthenium dye which is a light absorbing material sandwiched between glass and a electrolyte having a layer of titania that absorbs electrons to become an electric current; G24 Innovations of Wentloog Environmental Center, Wenloog, Cardiff, CF3 2EE, United Kingdom, (44) 29 2083 7340, having a website: www.g24i.com as of Feb. 1, 2011, which makes dye-sensitive solar cells or thin film (DSSC or DSTF) using ruthenium or organic dyes and titanium dioxide.

Nanotechnology is presently being used to create more efficient solar cells. For example, QDSoleil, Inc. of 2625 Hanover Street, Palo Alto, Calif. 94304, (650) 906-9230 having a website: www.qdsoleil.com as of Aug. 29, 2001, which is a subsidiary of Nanosys, Inc. having the same address, (650) 331-2101, and a website: www.nanosysinc.com as of Aug. 29, 2011, has entered into a strategic alliance with Samsung Electronics regarding co-development of solar energy products. The company is using inorganic quantum dots or nanocrystals, nanoscatterers and light capture materials, nanoparticles, nanorods, nanowires, semiconducting inks, and materials for dual nanocrystal and hybric nanocrystal designs.

The article “Solar-cell thinner than wavelengths of light hold huge power potential” which was published on the website: http://www.physorg.com/print204827475.html, as of Sep. 28, 2010, discusses the positive effects of providing a top layer including a patterned, roughened scattering layer which may have a green coloration. This technology can possibly result in more than a ten fold increase in the energy being absorbed by next generation solar cells due to so-called “light trapping.”

A graph created by the NREL, that is, the National Renewable Energy Laboratory and published on the internet at the website: http://en.wikipedia.org/wiki/File:PVeff(rev100921).jpg, as of Jan. 5, 2011, shows the relative efficiency of various modern solar cells in research lab settings, and the entirely of this publication is hereby incorporated by reference herein. It can be readily understood that some or all of the different types of solar cells and solar modules presently in production which are discussed herein, and which have been the subject of the research and development efforts and published results indicated in the NREL graph recited above could possibly be used to make solar arrays resembling natural foliage of the present invention.

The following U.S. Patents are directed to photovoltaic roofing or shading applications: U.S. Pat. No. 4,636,579, U.S. Pat. No. 5,385,848, U.S. Pat. No. 5,433,259, U.S. Pat. No. 5,478,407, U.S. Pat. No. 5,482,569, U.S. 2002/0129849, and U.S. 2002/0134422, the complete content of all of these patents and patent applications hereby being incorporated by reference herein. Further, the following U.S. Patents are directed to photovoltaic lights or signs: U.S. Pat. No. 4,200,904, U.S. Pat. No. 4,224,082, U.S. Pat. No. 4,281,369, U.S. Pat. No. 4,718,185, U.S. Pat. No. 4,841,416, U.S. Pat. No. 4,989,124, U.S. Pat. No. 5,149,188, U.S. Pat. No. 5,564,816, U.S. Pat. No. 6,060,658, U.S. Pat. No. 6,455,767, U.S. D353,014, the complete content of all of these patents hereby being incorporated by reference herein.

Solar cells have often been made in panels which comprise a relatively rigid material such as crystalline silicon or crystalline gallium arsenide. However, photovoltaic solar cells can also be made in the form of flexible plastic thin film, such as Powerfilm ® made by PowerFilm, Inc., which holds both U.S. Pat. No. 6,300,158, and U.S. Pat. No. 5,385,848, the complete content of these patents hereby being incorporated by reference herein. Solar cells have also been made in the form of textiles and fabrics, or alternatively, they can be affixed to textile and fabric materials as taught in U.S. Pat. No. 4,768,738, U.S. Pat. No. 5,478,407, U.S. Pat. No. 6,237,521, and U.S. Pat. No. 6,224,016, the complete content of all of these patents hereby being incorporated by reference herein. The following U.S. patents and patent applications relate to solar cells, and in particular, many specifically relate to making thin film solar cells: U.S. Pat. No. 4,609,770, U.S. Pat. No. 4,670,293, U.S. Pat. No. 4,689,874, U.S. Pat. No. 5,584,940, U.S. Pat. No. 5,674,325, U.S. Pat. No. 5,863,354, U.S. Pat. No. 6,160,215, U.S. Pat. No. 6,168,968, U.S. Pat. No. 6,211,043, U.S. Pat. No. 6,224,016, U.S. Pat. No. 6,271,053, U.S. Pat. No. 6,294,722, U.S. Pat. No. 6,310,281, U.S. Pat. No. 6,327,994, U.S. Pat. No. 6,380,477, U.S. Pat. No. 6,437,231, U.S. Pat. No. 6,543,725, U.S. Pat. No. 6,552,405, U.S. 2001/0020485, U.S. 2002/0000242, U.S. 2002/0092558, U.S. 2002/0139411, and U.S. 2002/0153037, U.S. 2002/0182769, U.S. 2003/0029493, U.S. 2003/0041894, U.S. 2003/0113481, U.S. 2003/0127127, U.S. 2003/0127128, the complete content of all of these patents and patent applications hereby being incorporated by reference herein. Some of the advances and reduction in the cost of photovoltaic solar cells is expected to derive from the ability to make extremely thin film solar cells.

Alternately, photovoltaic solar cells can also be made by painting or otherwise coating the surfaces of a desired substrate. Other electronic devices such as capacitors, resistors, transistors can also be made in this manner, and these can be included and used in combination with a solar cell. For example, see U.S. Pat. No. 6,099,637, U.S. Pat. No. 6,124,378, U.S. Pat. No. 6,480,366, U.S. Pat. No. 6,576,290, U.S. 2002/0157702, U.S. 2002/0158584, and U.S. 2003/0141417, by James E. Cordaro, and also U.S. Pat. No. 4,414,252 to Curtis M. Lampkin, the complete content of all of these patents and patent applications hereby being incorporated by reference herein. Further, A. Paul Alivisatos, a professor of chemistry at University of California, Berkeley and others at Lawrence Berkeley National Laboratory are developing solar cells consisting of nanorods dispersed in an organic polymer or plastic which can be painted onto a surface. These researchers anticipate making solar cells which can absorb light having several different colors and wavelengths in order to better span the spectrum associated with sunlight. In addition, Neal R. Armstrong in the Department of Chemistry and others at the University of Arizona, are working to develop organic molecules that self-assemble or organize from liquid into efficient solar cell coatings, thus creating organic solar cell thin-films.

### Controllers and Power Optimization

One of the practical problems associated with prior attempts to create solar arrays resembling natural foliage concerns the failure to recognize or to efficiently solve the problems associated with the unavoidable variation in the magnitude of sunlight provided on different sides of a solar array resembling natural foliage during the day, and also the related operational problems caused by the inadvertent shading of adjacent solar cells and modules. In brief, due to shading or disparate light conditions there could be a mismatch in the electrical output being produced by the various solar cells and solar modules and a reverse bias could then be created, and these conditions can trigger either diodes or switches to shut down those solar modules which are not then producing as much electrical output. And so it can be a case of all or nothing, and the electrical output produced by the solar cells and solar modules which are linked together then either match one another closely and they all work, or those solar modules producing less electrical energy output and which do not meet a certain tolerance field or threshold value get shut off and bypassed by either conventional diodes or switches.

For example, in an abstract and non-limiting hypothetical solar array resembling a palm tree having eight solar modules, one of the solar modules could be producing 20 volts at 4 amps, two could be producing 10 volts at 4 amps, two others producing 7.5 Volts at 4 amps, two more producing 2.5 Volts at 4 amps, and one producing 0 Volts. Given these large mismatches in voltage output, it is then possible for the diodes and switches associated with more conventional solar installations to shut off or bypass many of the solar modules and for most of the energy being produced by the solar array to then simply be lost. In order to better harvest the output being produced by the various solar modules in a solar array, a different structure and practical solution is required.

The present invention teaches monitoring and controlling the electrical activity of individual solar cells and/or solar modules, and also monitoring and controlling the electrical activity and the current flowing between different solar cells and/or solar modules included within the larger group of solar cells and/or solar modules used in a solar array resembling a palm tree in order to optimize the overall electrical energy output produced by a solar array of the present invention. Given the abstract and non-limiting hypothetical example of a solar array resembling a palm tree having eight solar modules provided above, let us suppose for illustrative purposes that one of the eight hypothetical solar modules on the solar array resembling a palm tree was producing 20 volts at 4 amps, two were producing 10 volts at 4 amps, two were producing 7.5 Volts at 4 amps, two were producing 2.5 volts at 4 amps, and one was producing 0 volts, the total output given the use of more conventional diodes and switches could then be limited to only the one solar module producing 20 volts at 4 amps for 80 watts of power. However, using monitoring and control devices having the ability to monitor and control the electrical activity of individual solar cells and /or solar modules, and also the electrical activity and the current flowing between different given solar cells and/or solar modules within the larger group of solar cells and/or solar modules included in a solar array resembling a palm tree, it would be possible, e.g., for the output of the two solar modules producing 10 volts at 4 amps to be added together in series to produce 20 volts at 4 amps, and the output of the two solar modules producing 7.5 volts at 4 amps to be added in series along with the two solar modules producing 2.5 volts at 4 amps to produce another 20 volts at 4 amps and for these to be then electrically coupled to the same circuit as the one solar module producing 20 volts at 4 amps to make possible a greater yield of electrical energy from the solar array, and in particular, 60 volts at 4 amps for 240 watts of electric power. Further, it can be readily understood that given a different structure and set of circumstances one or more solar cell and/or solar module could be selectively coupled in series and/or parallel in order to optimize the performance and power output of a solar array resembling natural foliage. Accordingly, the present invention can provide superior performance.

In addition, the use of electrical energy storage means such as capacitors and batteries can also provide another way of well harvesting electrical energy output from a solar array. In particular, when there is a mismatch in the electrical output from several solar cells and/or solar modules due to disparate light conditions or direct shading, the solar cells and/or solar modules can be operatively coupled to electrical energy storage means such as capacitors or batteries. For example, capacitors can be used to store up sufficient electrical energy from under-producing solar cells and/or solar modules to match the output coming from the solar cell and/or module producing the most voltage, or otherwise hit an engineered target range of operational voltage associated with the system design.

Again, the present invention teaches means for electronic monitoring and control including means for monitoring and controlling the electrical current, voltage, and output of each solar cell and/or solar module, and the electrical current, voltage, and output flowing between each of the solar cells and/or solar modules included in a solar array resembling natural foliage, and continuously changeably selecting at least two different solar cells located on at least two different solar modules for simultaneous operation from the larger group of solar modules in order to maximize the combined electrical energy output of the larger group of solar modules when a plurality of the solar modules are exposed to disparate light intensities, thereby optimizing the overall electrical energy output produced by a solar array of the present invention. Accordingly, it can be readily understood that the means for electronic monitoring and control can include what essentially comprises an electronic brain which may include one or more devices, e.g., a central processing unit, a controller, a micro-controller, an integrated circuit, a computer and the associated software for making intelligent, smart, and continuous real time selections for the purpose of optimizing the efficiency and operation of the solar array and maximizing its electrical energy and power output.

Other means for electronic monitoring and control and maximizing the electrical energy output of a solar array resembling a palm tree are possible and anticipated by the present invention. The structures, devices, and methods taught in the present invention can provide superior operational performance relative to the teachings associated with prior art efforts to create solar arrays resembling natural foliage because they provide for a greater harvest of the electrical energy being produced by the component parts of a solar array. Examples of devices for monitoring, controlling, and optimizing the operational performance and maximizing the electrical energy and power output of a solar array of the present invention, include, but are not limited to, the following devices and services:

Enphase Energy of 201 1^{st} Street, Petaluma, Calif. 94952, having the website: http://www.enphase.com as of Aug. 3, 2011, and phone: (877) 797-4743 is a manufacturer of microinverters such as their model M215 which performs DC to AC power conversion on a per-module basis, and which comes with a 25-year limited warranty. These microinverters are then normally connected in parallel AC branch circuits. Further, the company's “Envoy Communications Gateway” networks with each microinverter and can transmit performance information to the internet. In addition, their “Enlighten” software enables customers to monitor and manage their solar power systems 24 hours a day. The company also offers an integrated “Environ” product which monitors and controls the temperature of a home, office, or another structure. In brief, these product can improve the efficiency and reliability of a solar power installation.

SolarEdge of 900 Golden Gate Terrace, Suit E, Grass Valley, Calif. 95945, having the website: http://www.solaredge.com as of Aug. 3, 2011, and phone: (530) 273-3096 is a manufacturer of “Power Optimizers” which may be imbedded such as their model PB250-CSI, or added onto solar modules such as their OP250-LV. These power optimizers employ DC-DC conversion allowing them either boost or buck the output voltage of the module without changing the output power, and can provide over 98% peak efficiency. The devices use a highly optimized algorithm that ensures that each module is kept at maximum power production and which prevent power losses even given solar module mismatches or partial shading conditions. The company uses a fixed string voltage at the optimal point for DC to AC inversion regardless of the number of modules in a string, their performance or the environmental conditions. SolarEdge also produces single and three phase solar PV inverters. They also offer a “SolarEdge PV Monitoring Portal,” a “Module Monitoring” web-based application, and “Monitoring Combiner Box.” These devices enable module-level, string-level and system-wide monitoring of a solar installation.

Tigo Energy of 420 Blossom Hill Road, Los Gatos, Calif. 95032, having the website: http://tigoenergy.com as of Aug. 3, 2011, and phone: (408) 402-0802, makes a “Module Maximizer” such as their model MM-ES50 which is connected to each solar module or panel and uses an impedance matching technology to extract the maximum power form each module. This technology is different from others which use micro-inverters or DC-DC voltage conversion. Further, the “Module Maximizer” can increase the output of a conventional solar panel by up to 20%, and it is 99% efficient and so produces little heat which could lead to degradation of a solar module. The “Module Maximizers” can either be wired in series or parallel depending on the particular application. The Tigo Energy solution is capable of quickly finding the maximum operating state for each solar module and maintain system stability during cloud cover or shading. In addition, the company offers “MaxiManager” software products which provide real time monitoring and trouble shooting for operators or owners of a solar installation.

Power-One of 740 Calle Plano, Camarillo, Calif. 93012, having the website: http://www.power-one.com/renewable-energy as of Aug. 3, 2011, and phone: (805) 987-8741, makes a variety of string inverters including the “Aurora Micro” which is a 300 watt micro-inverter, the “Aurora Optimizer” which uses DC-to-DC technology, and the “Aurora Uno” and “Aurora Trio” since and three phase inverters. The company also offers several central inverter such as the “Aurora Lite, Plus, and Ultra.” Further, Power-One has a number of monitors and software for monitoring and controlling solar installations including their “Aurora Vision,” “Aurora Universal,” “Aurora Environmental,” “EVO Easy Control,” and “Desktop” products. Power-One has also recently purchased the company SolarMagic from National Semiconductor.

SolarMagic has produced charge controllers including integrated circuits, DC-DC power optimizers, microinverters, gate drivers, voltage regulators, sensing and detection devices, microcontrollers, and power optimizer chipsets for improving the harvest of electrical energy and overall efficiency of a solar installation. The company has also provided wireless radio frequency communication and remote shutdown options with its solar energy related products. The reference diagrams provided on the website http://www.national.com/en/solarmagic.com as of Aug. 3, 2011 also show bias voltage supply devices, input current and voltage sense amplifiers, output current and voltage sense amplifiers, quasi-resonant flyback devices, rectified full wave Sine-to-Sine bridges, temperature sensors, filters, switching power supplies, regulators, full bridge drivers, digital and panel controls, microcontrollers, RF receivers, h-bridge power stages, as well as other electronic devices for improving the overall efficiency and also monitoring and controlling a solar installation.

Accordingly, it can be readily understood that adaptors, AC disconnects, amplifiers, batteries, battery cables, battery controllers, battery status meters, bias voltage supply devices, breakers, capacitors, central processing units, chips, circuit breakers, coils, tesla coils, computers, conduit, connectors, controllers, charge controllers, micro-controllers, control panels, digital and panel controls, converters, combiners, DC disconnects, DC-DC power optimizers, diodes, drivers, gate drivers, full bridge drivers, extension cords, filters, fuses, generators, grid tie power centers, ground fault switches, h-bridge power stages, inductors, integrated circuits, inverters, micro-inverters, junction boxes, lights, meters, metal oxide semiconductors, output current and voltage sense amplifiers, off grid power centers, power supplies, power optimizer chipsets switching power supplies, quasi-resonant flyback devices, rectified full wave Sine-to-Sine bridges, regulators, RF receivers, repeaters, resistors, sensors, sensing and detection devices, software, shot reactors, static var compensators, surge protectors, switches, temperature sensors, thyristors, transformers, transistors, bi-polar junction transistors, voltage regulators, wiring, wireless RF communication devices, wireless transmitters, wireless receivers, wireless repeaters, and other electronic components or devices may be used or electrically coupled in functional relation with a solar array resembling natural foliage of the present invention.

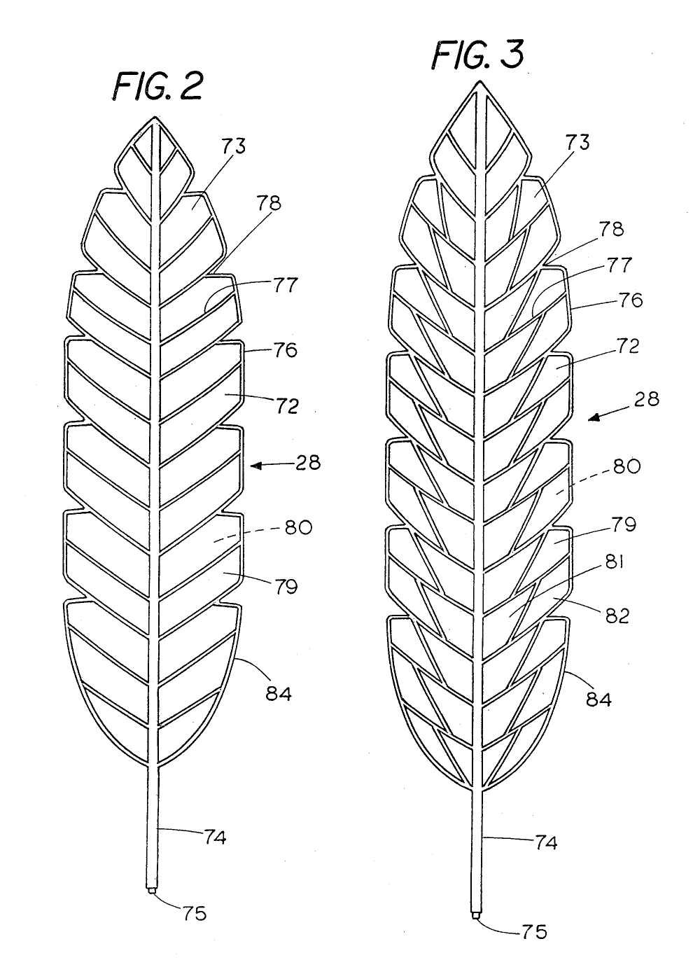

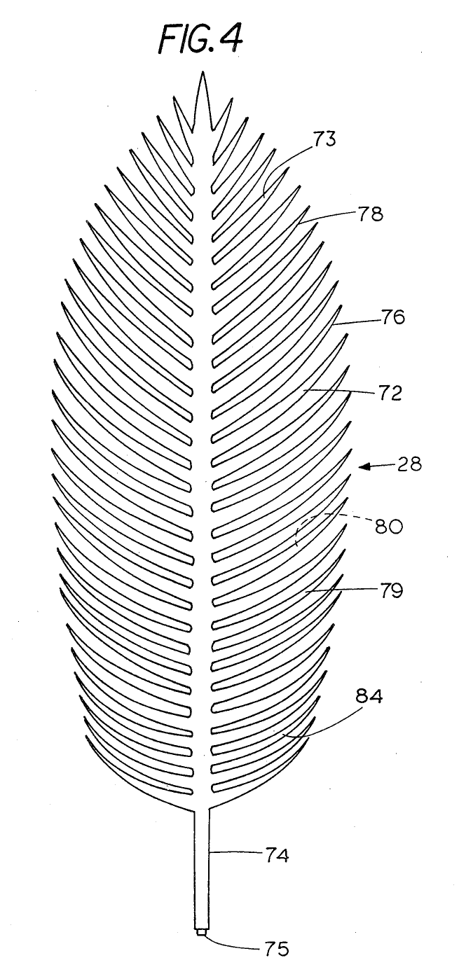

FIG. 2 is a top plan view of an artificial leaf or palm frond 72 that includes at least one solar panel or solar module 28 for use with an artificial palm tree 29 that constitutes a solar array 30. Over two hundred varieties of palms exist in nature, and this particular embodiment generally resembles a banana leaf or palm frond. The artificial palm frond 72 includes a stem portion 74, a blade portion 84, at least one electrical connection or socket 75, a top side 79, a bottom side 80, an edge 76, a plurality of notches 78, and can also include a plurality of artificial veins 77. In some embodiments, the color of the solar cells 73 can be a medium or dark green, and that of the veins 77 and edge can be a lighter green, yellow, or brown. Further the color of the individual solar cells 73, and also both the top side 79 and bottom side 80 of the artificial palm frond 72 can be varied in different locations so as to create a natural appearance. The structure and color of the artificial palm frond 72 can also be selected to maximize light absorption from different angles of incidence, and if desired, the structure and color can also be selected for its ability to coincidentally reflect light which can then be absorbed by other nearby artificial palm fronds 72. In the embodiment shown in FIG. 2, the solar module 28 can include at least one solar cell 73. Depending upon their particular structure and electrical properties, the solar cells 73 can be wired in series, or alternately they can be wired in parallel with other solar cells 73. Likewise, depending upon their structure and electrical properties, the solar panels or modules 28 can also be wired in series or parallel. The bottom side 80 of the artificial palm frond 72 can consist of plastic material such as polyethylene, polypropylene, polyurethane, a metal material such as aluminum, copper, stainless steel, or a ceramic material. Flexible plastic or polyurethane materials can be advantageous for use, and in particular, when an artificial palm frond 72 is configured to resemble one for a coconut palm or a date palm tree. In the embodiment shown in FIG. 4, the palm fronds associated with these palm trees include a plurality of highly flexible separate blades. Artificial palm fronds 72 and leaves which are flexible can be advantageous when attempting to simulate a natural appearance. Moreover, artificial leaves, palm fronds, and branches which are flexible also enhance the ability of these structures to be self-cleaning, as wind, morning dew, and rain can then wash their surfaces clean. In the embodiment shown in FIG. 2, the stem 74 portion of the artificial palm frond 72 measures approximately one and one half feet in length and is approximately one inch in diameter. The blade 84 portion is approximately eight feet long and two feet wide, and has a working surface area of approximately twelve square feet. Accordingly, an artificial palm tree 29 or solar array 30 including thirty two such artificial palm fronds 72 has a working surface area of 384 square feet, and so could provide double the power output of the model solar array discussed earlier that used a plurality of solar modules 28 consisting of PowerFilm, Inc.'s R15-1200 Powerfilm ® photovoltaic thin film having a working surface of only 192 square feet. And an artificial palm tree 29 or solar array 30 including thirty six such artificial palm fronds 72 and solar modules 28 would have a working surface area of 432 square feet, and provide even more power. Accordingly, a network including 660 such solar arrays along a one mile stretch of highway could meet the needs of approximately 200 average homes.

FIG. 3 is a top plan view of an artificial palm frond 72 generally similar to that shown in FIG. 2. However, the artificial palm frond 72 shown in FIG. 2 further includes a middle portion 81 and also peripheral portion 82, each of these portions including a plurality of separate solar cells 73. The color as well as other physical and electrical properties of the middle portion 81 and peripheral portion 82 of the artificial palm frond 72 can be selectively varied, as desired, in order to enhance its efficiency and natural appearance. Depending upon the structure and electrical characteristics of the solar cells 73 being used, the use of more numerous solar cells 73, and the location of solar cells 73 in both the middle portion 81 and also the peripheral portion 82 can increase the efficiency of the solar module 28 when partial shading of the artificial palm frond 72 would occur.

FIG. 4 is a top plan view of an artificial palm frond 72 generally similar to that shown in FIGS. 2 and 3. However, this particular embodiment includes a plurality of separate and relatively thin blades 84. Accordingly, this embodiment of an artificial palm frond 72 has a structure configured to resemble the palm fronds associated with coconut palms and date palms.

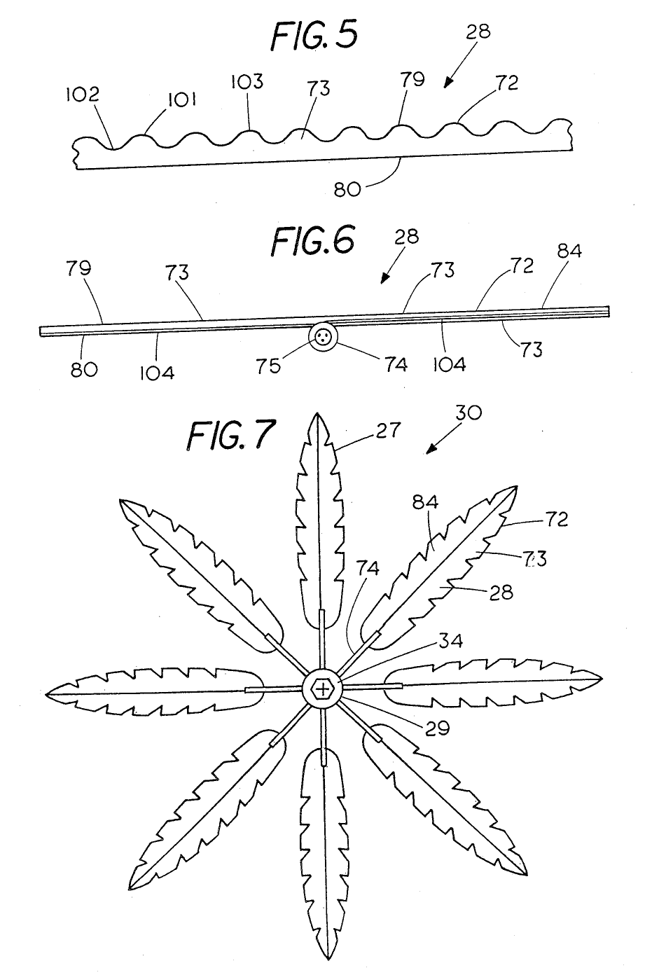

FIG. 5 is an enlarged side view of an alternate solar module 28 including at least one solar cell 73 having a textured surface 103 including a plurality of peaks 101 and valleys 102. A textured surface 103 which is not perfectly planar and smooth can increase the effective working area of a solar module 28 and solar cell 73. Accordingly, the use of a textured surface 103 can sometimes enhance the light absorption properties, but also the light reflecting properties of a solar module 28 and solar cell 73. Many plant species have leaves or exterior surfaces that are not perfectly smooth, rather they commonly include textured surfaces, convolutions, or other irregularities. For example, many forms of seaweed have textured, ribbed or convoluted surfaces including numerous peaks and valleys, and this can provide greater surface area both for collecting light, but also for absorbing nutrients from the sea. Photovoltaic solar cells including textured surfaces are known in the prior art, such as U.S. Pat. No. 6,552,405 granted to Sugawara et al. and assigned to Kyocera Corporation, the complete contents of this patent hereby being incorporated by reference herein.

FIG. 6 is a side cross-sectional view of an alternate solar module 28 including an integral capacitor 104. The capacitor 104 can consist of a relatively thin layer which can be formed or deposited by conventional means including but not limited to painting, coating, vapor and also powder deposition upon one of the substrates used to make the solar module 72. U.S. Pat. No. 6,480,366 and U.S. Patent Application 2002/0158584 by James F. Cordaro teach painted capacitor energy storage, the complete contents of these two patent documents hereby being incorporated by reference herein. As shown on the left side in FIG. 6, an integral capacitor 104 can be positioned on the bottom side 80 of an artificial leaf or palm frond 72, thus the top side 79 can be used exclusively for absorbing light. Alternatively, as shown on the right side in FIG. 6, an integral capacitor 104 can be positioned between the top side 79 and bottom side 80 of an artificial leaf or palm frond 72, thus both the top side 79 and bottom side 80 can be used to absorb light. An artificial leaf or palm frond 72 including a solar module 28 including at least one solar cell 73 can be made in the general configuration shown on the left side of FIG. 6, or alternatively, in the general configuration shown on the right side of FIG. 6. As shown, it is also possible to combine the two structures illustrated in FIG. 6 when making a single solar module 72. Moreover, a plurality of solar modules 28 including capacitors 104 can be selectively positioned in functional relation to a solar array 30 to maximize both energy production and energy storage.

FIG. 7 is a top plan view of a layer 27 including a plurality of artificial palm fronds 72. The artificial palm fronds 72 each include a solar module 28 including at least one solar cell 73, and can be used to create an artificial palm tree 29 that forms solar array 30. In the embodiment shown in FIG. 7, the layer 27 includes eight artificial palm fronds 72 each having a stem 74 approximately one and one half foot long. The blade 84 has a maximum width of approximately two feet, a length of approximately eight feet, and a working surface area of approximately twelve square feet. Other dimensions for the stem and blade portions can be used. However, given the configuration and dimensions shown in FIG. 7, a maximum blade 84 width of approximately three feet is all that can be attempted without causing portions of adjacent artificial palm fronds 72 to overlap one another. When less than eight artificial palm fronds 72 are used, then the width dimension of the blades 84 can be more easily increased. Generally, it is most advantageous to use between five and ten artificial palm fronds 72 in a single layer 27. As shown in FIG. 7, the artificial palm fronds 72 including solar modules 28 can be removably secured to the top portion 34 of the trunk 21 of an artificial palm tree 29.

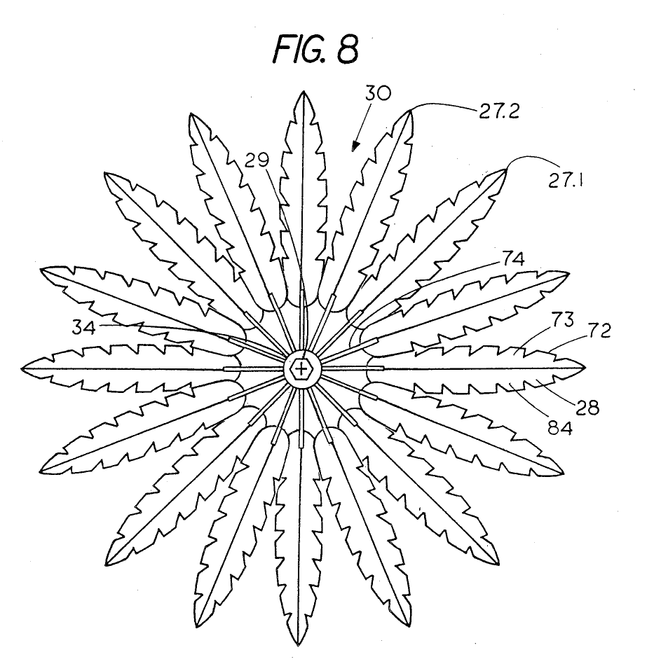

FIG. 8 is a top plan view of two partially overlapping and staggered layers 27 of artificial palm fronds 72, each including a solar module 28 including at least one a solar cell 73 for use with an artificial palm tree 29 that consists of a solar array 30. In particular, shown is a first layer 27.1, and also a second layer 27.2 which is in a superior position relative to the first layer 27.1. Some photovoltaic solar panels or modules that are made with a plurality of solar cells which are wired in series can suffer a substantial degradation in their power output when even a single solar cell is shaded. And some of these solar panels or modules cannot be wired in parallel in order to simply correct for this problem, as those solar cells which are being shaded can still unduly influence the overall power output of the solar panel or solar module. However, as recited above in greater detail in the present application, it is possible to introduce electronic devices including, but not limited to monitors and controllers for monitoring and controlling the electrical activity, output and performance of individual solar cells, or groups of solar cells which are present in a solar module, as well as the electrical activity between different solar modules, and then appropriately turn off, isolate, combine, or otherwise control the current either flowing from or being directed towards a given solar cell or solar module. In this way, any undesired effects which might be caused by shading, or by a solar cell possibly becoming damaged or rendered inoperable can be avoided. Accordingly, the operational efficiency of the solar module and solar array can be optimized. One of the advantages of flexible thin film solar cells and also those which can be made by painting or other coating processes is that they can be less prone to suffering a dramatic reduction in their power output given low light conditions, shading, or damage to individual solar cells. In many cases, when a portion of the solar cell is being shaded, then the power output of that particular area is effected, but there is then little or no collateral effect upon other solar cells in a given solar module.

It can be advantageous to design a solar array in order to maximize its power output during operation. At some point, the introduction of a greater number of artificial palm fronds, or a larger size artificial palm frond, or additional layers of artificial palm fronds can introduce more substantial shading and this can provide diminishing returns with regards to the efficiency of the solar array. It can also be advantageous to consider and factor in the relative height, path, intensity, and position of the sun at various times of the year when designing and installing a solar array. In some cases, a single layer including between five and ten artificial palm fronds can provide optimal efficiency, and the appearance of these solar arrays can then more closely resemble certain palm species such as coconut palms. In other cases, a plurality of layers including solar modules consisting of artificial palm fronds each including a plurality of relatively thin blades can be more suitable, and in particular, when attempting to imitate the appearance of date palms.

Another consideration is whether to provide solar cells on only the top side, or on both the top side and bottom side of some or all of the artificial palm fronds. Given the presence of light colored sand in desert conditions beneath a solar array, substantial light can be reflected from the surrounding ground surface to the solar modules overhead. Light can also be reflected by the artificial palm fronds to at least partially illuminate the top and bottom surfaces of other adjacent artificial palm fronds including solar cells. In the past, most conventional photovoltaic solar cells have been black or dark blue in coloration, as this was thought to maximize light absorption. However, in some circumstances it is possible for medium and dark green coloration to actually maximize the total light absorption of a solar array when the effect of reflected light as between various artificial leaves or palm fronds is considered. Further, the use of dark blue or black coloration can be associated with higher operating temperatures and this can possibly result in more rapid degradation of an artificial palm frond having a solar module including at least one solar cell over several decades of use.

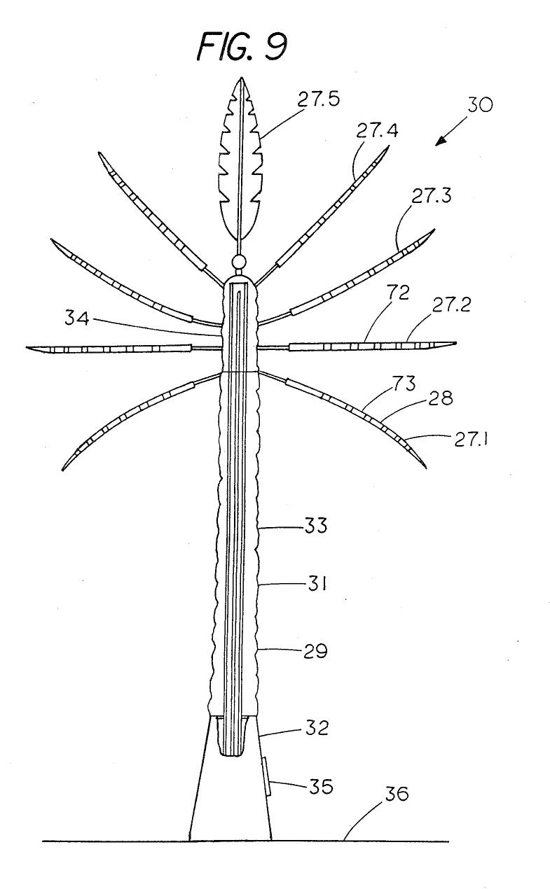

FIG. 9 is a side perspective view of an artificial palm tree 29 generally similar to the embodiment shown in FIG. 1 forming a solar array 30, and showing the orientation of five layers 27 of artificial palm fronds 72 each including a solar module 28 including at least one solar cell 73. In the embodiment shown in FIG. 9, the artificial palm fronds 72 on the inferiormost first layer 27.1 are orientated downwards at approximately 45 degrees, whereas those on the second layer 27.2 are orientated approximately horizontally. The artificial palm fronds 72 on the third layer 27.3 are orientated upwards at approximately 30 degrees, whereas those on the fourth layer 27.4 are orientated upwards at approximately 45 degrees. The fifth layer 27.5 of artificial palm fronds 72 is orientated upwards between 45 and 90 degrees. The different orientations of these layers and also the staggered placement of the artificial palm fronds 72 can permit the capture of substantial direct light and also reflected light by the solar array 30. The structure and configuration shown in FIG. 9 can also provide a large resulting working area, and tends to minimize counterproductive shading of adjacent artificial palm fronds 72 and solar modules 28.

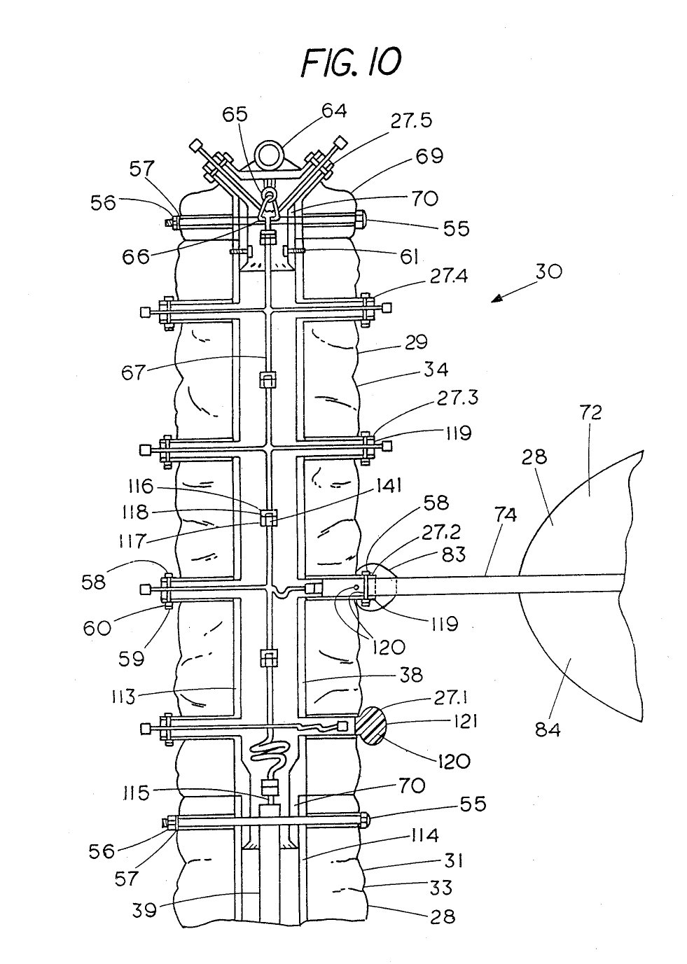

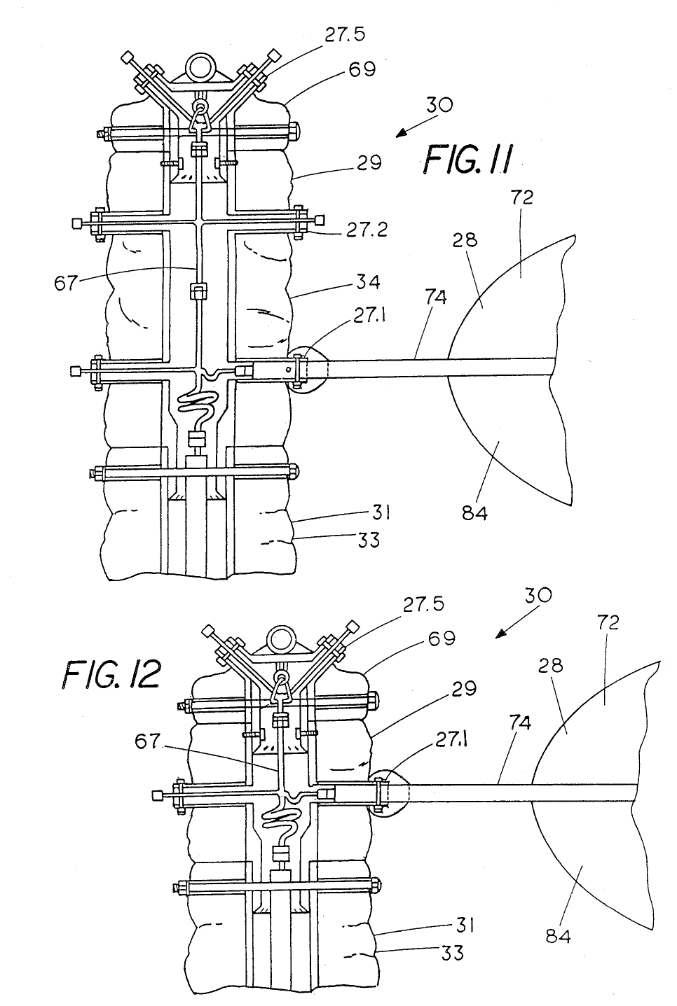

FIG. 10 is a side cross-sectional view of a top portion 34 of the trunk 31 of an artificial palm tree 29 including provision for four layers 27, and also of a cap portion 69 of the trunk 31 of an artificial palm tree 29 including provision for one layer 27.5 showing both internal and external components. The top portion 34 of the trunk 31 includes a top portion 113 of pole 38 that includes a sleeve 70 which can be inserted within the inner diameter of the bottom portion 114 of the pole 38. The sleeve 70 can be made integral to the top portion 113 of the pole 38, or can be secured by mechanical fasteners such as bolts 61, or can be welded thereto. Alternately, a sleeve 70 portion can extend from the bottom portion 114 of pole 38 and instead be received within the inner diameter of the top portion 113 of the pole 38. The sleeve 70 and top portion 113 of the pole 38 can then be further removably secured to the bottom portion 114 of the pole 38 with the use of a long bolt 55, washer 57, and nut 56. When the long bolt 55 is removed, the entire top portion 34 and cap portion 69 of the trunk 31 including a plurality of solar modules 28 can be lifted and removed using a rope or cable which can be attached to the external ring 64 present at the top of the cap portion 69 of the trunk 31. Conversely, the entire top portion 34 and cap portion 69 of the trunk 31 including a plurality of solar modules 28 can be simply lifted and installed using a rope or cable that can be attached to the external ring 64 present at the top of the cap portion 69 of the trunk 31. Accordingly, the process of installing, repairing, or renewing components of a solar array 30 is made fast and easy.

As shown in FIG. 10, the top portion 34 of the trunk 31 includes four layers 27, namely, layers 27.1, 27.2, 27.3, 27.4, and 27.5 of solar modules 28, and each layer 27 can include between five and ten artificial palm fronds 72 including or essentially consisting of solar modules 28. The conduit 39 containing and protecting the electrical wire 115 terminates a short distance from the top of the middle portion 33 of the trunk 31 so as to avoid it possibly becoming damaged during the installation of the top portion 34 of the trunk 31. The electrical wire 115 can include a plug 116 and socket 117 type connector 118 which can include locking means 141 for selectively locking the two subcomponents together so as to prevent accidental disconnection. Likewise, a plurality of electric power cords 67 can be used to connect each layer 27 of solar modules 28 to the other, or alternatively, to simultaneously connect all of the layers 27. The electric power cords 67 can be affixed to an internal ring 65 via a clip 66 and thereby be suspended vertically.

The cap portion 69 of the trunk 31 can also include a sleeve 70, or alternatively, can receive a sleeve 70 for properly positioning and securing the cap portion 69 to the top portion 34 of the trunk 31. The cap portion 69 can then be further removably secured by using a long bolt 55, nut 56, and washer 57. A portion of an artificial palm frond 72 including or substantially consisting of a solar module 28 is also shown in position in FIG. 10. The stem 74 of the artificial palm frond 72 is configured to fit within the inner diameter of the receptacle 119. The stem 74 can then be further secured using a bolt 58, nut 59, and washer 60 which can either serve to clamp the receptacle 119 about the stem 74 of the artificial palm frond 29, or alternatively, and as show in FIG. 10, the bolt 58 can pass through an opening 120 in the stem 74. The stem 74 can be provided with a plurality of alternate openings 120 for possible use so as to permit the selection of a particular orientation of the artificial palm frond 72 during installation, as desired. The wiring connection between the artificial palm frond 72 including the solar module 28 can be made by manual means and the use of wire nuts 53, but as shown in FIG. 10, the wiring connection is preferably made with the use of a plug 116 and socket 117 connector 118 including locking means 141 which is generally similar in structure and function with those used to connect the electrical wire 115 and the electric power cords 67, but being smaller in size. Many different styles and sizes of connectors 118 are commercially available and can be used. A seal 83 can be used to cover and protect the junction of the stem 74 with the receptacle 119, and so prevent the ingress of dirt, water, insects, or rodents which could cause damage to the solar array 30. When not all of the provided layers 27 or receptacles 119 are required or desired for use in a given solar array 30, a plug 121 can be used to seal the opening 120 associated with a receptacle 119.

FIG. 11 is a side cross-sectional view of an alternate top portion 34 of the trunk 31 of an artificial palm tree 29 including provision for two layers 27.1 and 27.2, and also a cap portion 69 including provision for one layer 27.5 for use in making a solar array 30 showing both internal and external components. As a result, the top portion 34 of the trunk 31 of an artificial palm three 29 can be removably secured and assembled using a component that includes provision for two layers 27.1 and 27.2, that is, if and when this configuration is desired.

FIG. 12 is a side cross-sectional view of an alternate top portion 34 of the trunk 31 of an artificial palm tree 29 including provision for one layer 27.1 and also a cap portion 69 including provision for one layer 27.5 for use in making a solar array 30 showing both internal and external components. As a result, the top portion 34 of the trunk 31 of an artificial palm three 29 can be removably secured and assembled using a component that includes provision for only one layer 27.1, that is, if and when this configuration is desired. The provision of multiple power cords 67 each providing sufficient wiring for one layer of solar modules 28 which can be easily coupled together can facilitate rapid assembly. The possible provision of alternate top portions 34 in one, two, or four layer 27 configurations makes it possible to easily assemble different resulting structures. Accordingly, the power generating capability and also the aesthetic appearance of a solar array 30 can be customized.

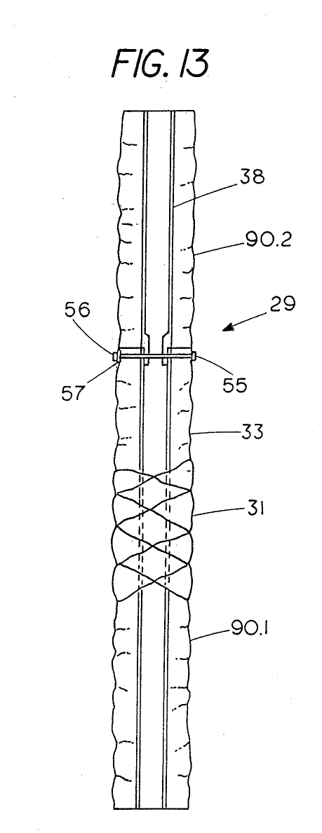

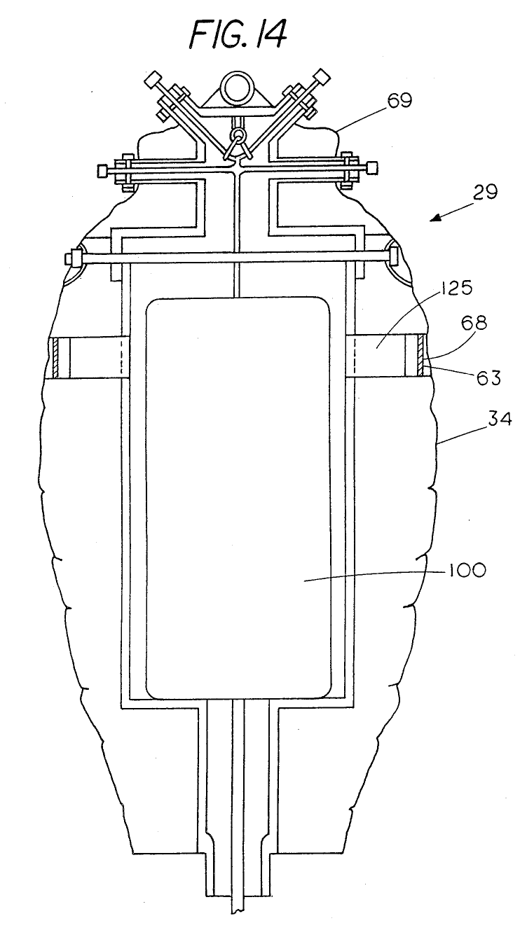

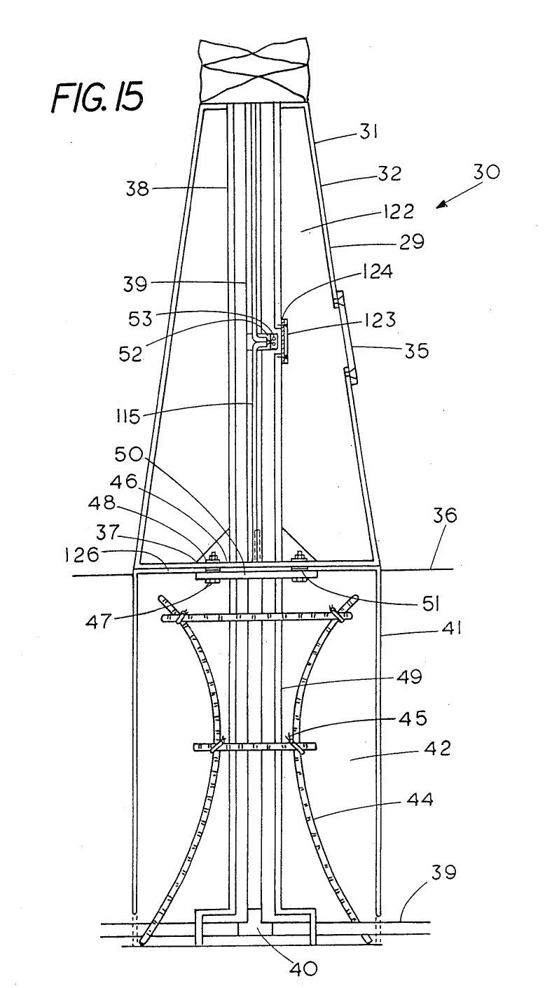

FIG. 13 is a side view of an alternate middle portion 33 of the trunk 31 of an artificial palm tree 29 with parts broken away. The middle portion 33 includes at least two segments or sections 90, and in particular, sections 90.1 and 90.2, which can be removably secured together with the use of a long bolt 55, nut 56 and washer 57 in order to determine the overall height of the resulting trunk 31 of an artificial palm tree 29, as desired. Shown in FIG. 13 is a section 90.1 having a length of eight feet, and another section 90.2 having a length of four feet. Accordingly, multiple sections 90.1 and 90.2 can be easily combined in various partial or complete combinations to create trunks 31 and artificial palm trees 29 having different heights. The configuration and texture of the outer surface of the trunk 31 can be made to resemble that of a palm tree by making the molds for these components from an actual palm tree. The trunk 31 can then be made of plastic, polyurethane, fiberglass, metal, ceramic, and also natural organic and fibrous materials in various combinations.

FIG. 14 is a side cross-sectional view of an alternate top portion 34 and cap portion 69 of a trunk 31 for use in making an artificial palm tree 29. As shown, the top portion 34 and cap portion 69 have greater width that the embodiment shown in FIG. 10, and this can provide space for accommodating and substantially concealing a transformer 100. A step-up transformer can be used to step-up the voltage being generated by the solar array so that it can be more efficiently carried over long distances. Conversely, a step-down transformer can be used to step-down the voltage being carried by a high voltage power line. A transformer can be connected to overhead transmission lines, or alternatively to buried power lines which can carry DC current or AC current. Shown is a duct 125 including a vent 68 having a screen 63 for permitting ventilation while preventing the entry of birds, bees, or other foreign matter.

FIG. 15 is a side cross-sectional view of the bottom portion 32 of a trunk 31, and also a footing 126 including a support platform 49 for an artificial palm tree 29 that forms a solar array 30 showing both internal and external components. As shown, the bottom portion 32 of the trunk 31 gradually widens as it approaches the ground surface 36, thus simulating the appearance of many palm tree species. The bottom portion 32 of the trunk 31 can include at least one access door 35 to an interior compartment 122. The support pole 38 can further include a cover 123 and a gasket 124 which permits access to a wire connection 52 between the solar array 30 and electric wire 115. The wire connection 52 can be secured by wire nuts 53, or alternatively, by other conventional fastening means such as bolts or screws associated with a junction box 54. The electric wire 115 can be protected from damage by a conduit 39 made of metal or plastic, and in particular, in areas where the soil, insects, or rodents could cause harm or degradation to the wire 115.

The base 37 of the pole 38 includes a reinforced flange 46 that provides several openings for the passage of bolts 47. The base 37 of the pole 38, and in particular, the inferior side of the flange 46 is configured to bear upon a footing 126 which can include a submerged platform 49 including a reinforced flange 50. The vertical alignment of the pole 38 can be adjusted at the junction of flange 46 and flange 50 with the use of one or more washers 51 when the bolts 47 and nuts 48 are secured. The platform 49 can include a stand-off at the inferior side for permitting the conduit 39 and conduit fitting 40 including the electric wire 115 to pass directly beneath, but also to permit the concrete 42 used in the footing 126 to substantially encompass the platform 49. The concrete 42 can be further reinforced by including metal rebar 44 therein. The rebar 44 can be configured as desired and secured with the use of tie wire 45 prior to pouring the concrete 42. A circular hole or pit can be drilled in the ground using power equipment and a circular or tube shaped form 41 can be inserted into the hole or pit for properly containing the concrete 42 when it is poured. It can be readily understood that the particular configuration, structure, and size of a footing 126 can vary depending upon the geology, soil conditions, climate, and seismic characteristics of the installation site.

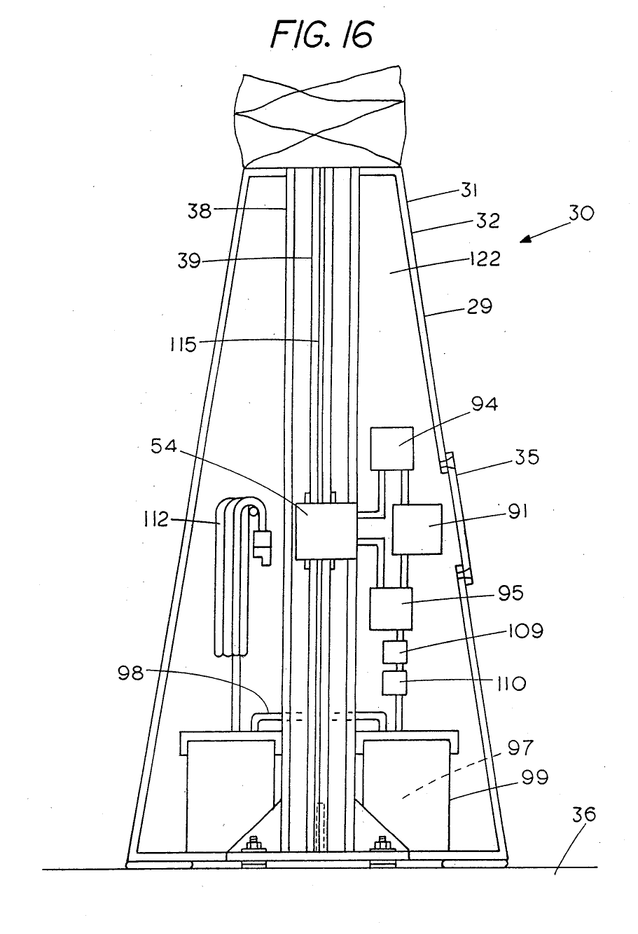

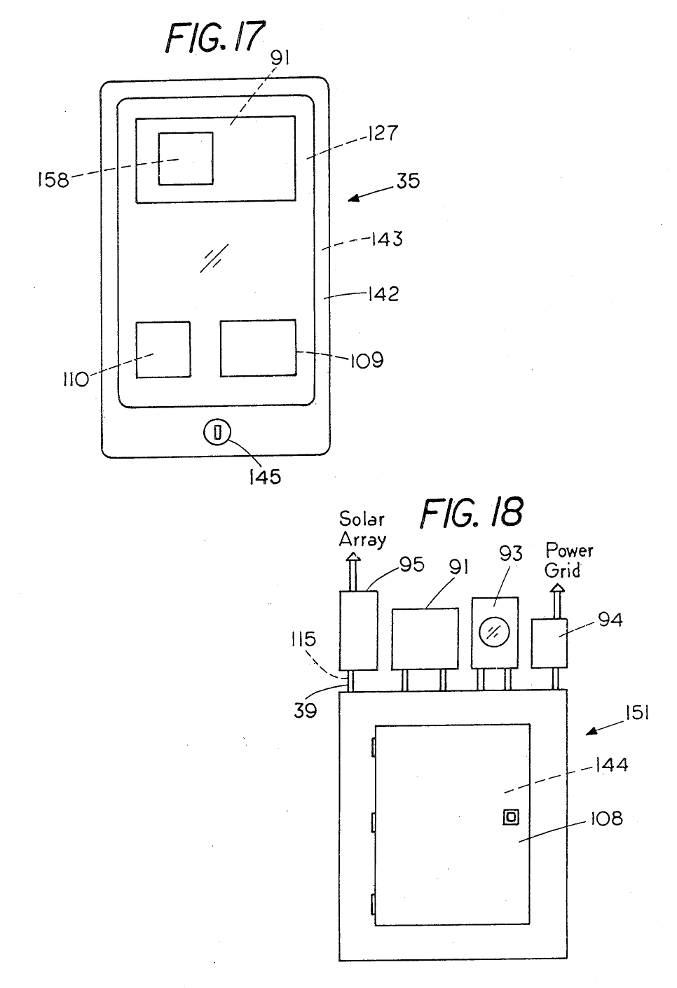

FIG. 16 is a side cross-sectional view of the bottom portion 32 of the trunk 31 and of an artificial palm tree 29 that constitutes a solar array 30 showing both internal and external components generally similar to that shown in FIG. 15. However, instead of the solar array 30 being directly connected by an electric wire 115 to a network of solar arrays and a solar power grid or conventional electric power grid, the solar array 30 further includes a number of devices which can be located internally. In particular, a solar array 30 can include in various partial or complete combinations, an inverter 91 such as a Sunnyboy brand grid-tie inverter made by SMA America, Inc. of Grass Valley, Calif., or those of PV Powered of Bend, Oregon for converting DC current to AC current, a converter for converting AC current to DC current, a transformer, a battery 97 and associated battery cables 98, a battery box 99, a junction box 54, a control panel, an AC circuit breaker, a DC circuit breaker, an AC disconnect 94, a DC disconnect 95, a meter, a ground fault switch, a power surge protection device, a fuse, a capacitor, a resistor, a transistor, a diode, a chip, a battery controller 109, a battery status meter 110, a generator, conduit 39 including suitable electric wire 115, a retractable extension cord including a plug, a light, an adapter for recharging small batteries, appliances and power tools, and, an electric power recharging cord 112 for recharging a vehicle such as an electric scooter, bicycle, car, boat, or aircraft. The recharging cord 112 can be mounted within the interior compartment 122 of the base 32 on an automatic retractable reel, whereas the end of the recharging cord 112 including the connector 118 can be located externally and be readily accessible for use. It can be readily understood that some of the devices and things recited in this paragraph can be combined in structure and function in the form of hybrid devices.

FIG. 17 is a top perspective view of an access door 35 to the interior compartment 122 of the bottom portion 32 of the trunk 31 of an artificial palm tree 29 which forms a solar array 30. As shown, the access door 35 can include a transparent window 127 on the exterior side 142 for viewing the status of one or more devices such as an inverter 91, a meter, an AC disconnect, a DC disconnect, a battery controller 109, and a battery status meter 110. A battery controller 109 can be used to prevent overcharging of a battery, and also to reverse electric power flow at night. As shown, the visual display 158 associated with these electronic devices, and the like, can be mounted near or directly to the interior side 143 of the access door 35, whereby these devices can be easily viewed and serviced. As shown, the access door can included a keyed lock 145, or other closure and locking means.

FIG. 18 is a perspective view of a grid-tie power center 151 which could be used in a typical residential installation in combination with one or more solar arrays 30 resembling natural foliage according to the present invention. Shown is an inverter 91 for converting DC current to AC current, an AC disconnect 94, a DC disconnect 95, a meter 93, a control panel 108 including circuit breakers 144, and conduit 39 containing suitable wire 115. A grid-tie power center 151, or alternately an off-grid power center, can also include or integrate in various partial or complete combinations a battery and associated battery cables, a battery box, a battery status meter, a battery controller, a ground fault switch, a surge protector, a converter, a transformer, an extension cord, a light, a generator, an adapter for recharging small batteries, appliances, and power tools, and an electric power recharging cord for recharging a vehicle such as an electric scooter, bicycle, car, or boat.

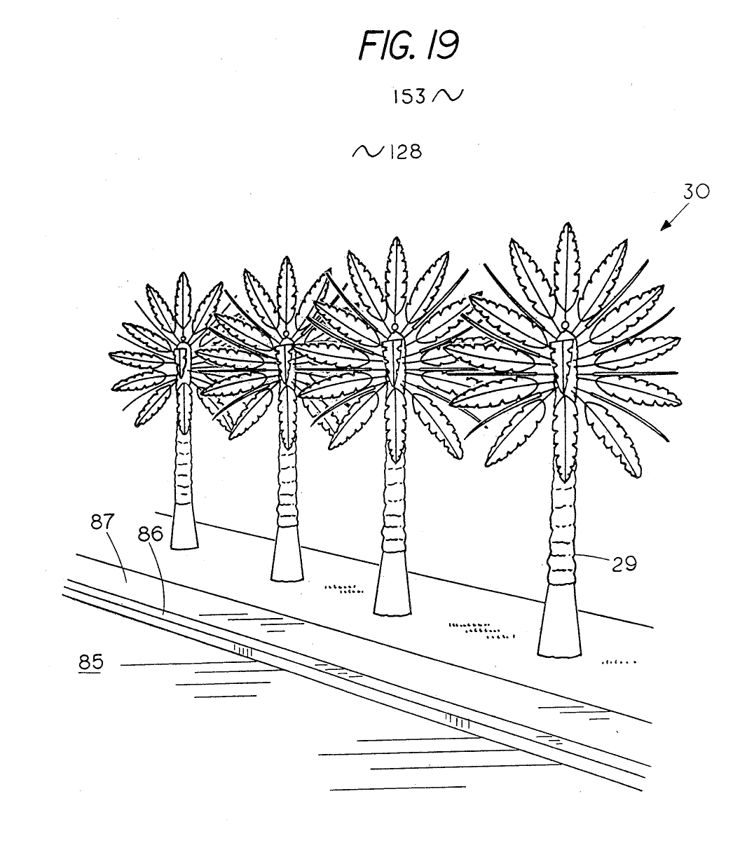

FIG. 19 shows a row 128 of artificial palm trees 29 that consist of solar arrays 30 on one side of a street 85. The solar arrays 30 have a structure configured to resemble natural foliage and can be placed in communication to create a network 153 of solar arrays 30 that constitute at least a portion of a solar power grid 154. Further, the solar arrays 30 can be individually connected to power transmission lines associated with a power grid. Alternatively, a plurality of solar arrays 30 can be connected together, and then connected as a group to power transmission lines. The solar arrays 30 can be wired together in series, or alternately in parallel. When a plurality of solar arrays 30 are wired together for connecting to an AC power grid, a grid-tie inverter can be used. The artificial palm trees 29 are aesthetically more pleasing than conventional overhead power lines, and also the sparse vegetation found by the sides of roads and highways in the Southwest area of the United States and other arid regions of the world. The artificial palm trees 29 are shown near a curb 86 and adjacent sidewalk 87. Besides providing clean and renewable electric power, the solar arrays 30 can also provide shade and serve as a windbreak. Unlike natural foliage which is difficult to maintain by the sides of roads and highways in the Southwest area of the United States and other arid regions of the world, an artificial palm tree 29 always has a healthy appearance, never needs watering, and requires little maintenance. In desert areas, the shade provided by artificial palm trees 29 can be used to facilitate the cultivation of natural foliage and agriculture. A network of solar arrays 30 can also be positioned along canals and pipelines. The power produced by a solar array 30 can be used to pump oil, or water, and also to desalinate and filter water for residential and agricultural use. Solar water heating devices such as those made by Maltezos S A of Athens, Greece can then be used to provide hot water. Solar arrays 30 can also be positioned alongside railways for providing power for electric trains. The ability to generate and distribute power where it is actually needed can result in logistical and economic efficiency. In this regard, the location, pattern, and density of public roads and highways generally well reflects the local population density and demand for energy. Accordingly, the creation of a network 153 of solar arrays 30, and at least one solar power grid 154 alongside public roads can be consistent with the local economy of scale.

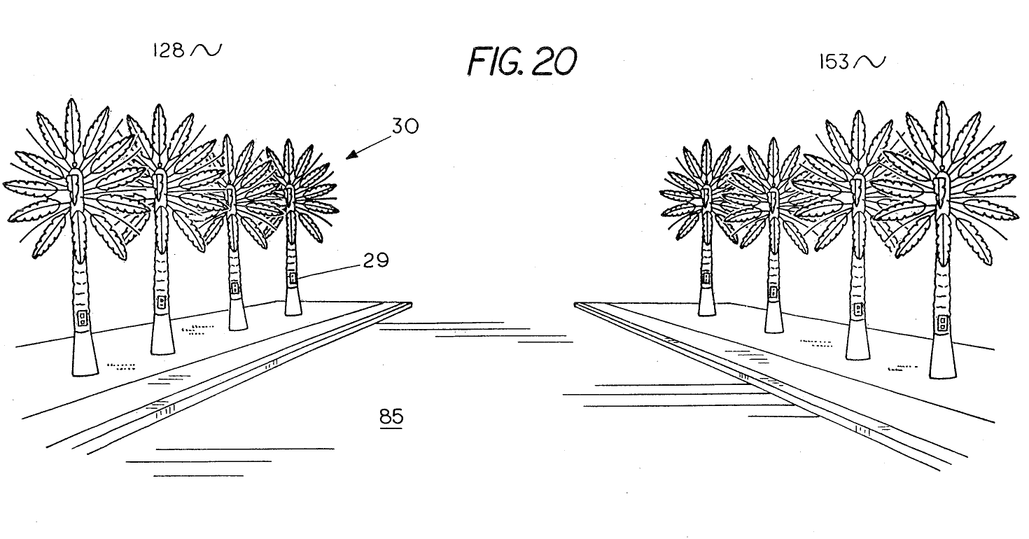

FIG. 20 shows a row 128 of artificial palm trees 29 that consist of solar arrays 30 located on both sides of a street 85. The solar arrays 30 have a structure configured to resemble natural foliage and can be linked together to create a network 153 of solar arrays 30 and a solar power grid 154. FIG. 20 conveys some sense of the structure and aesthetic impression created by a network 153 including a plurality of solar arrays 30.

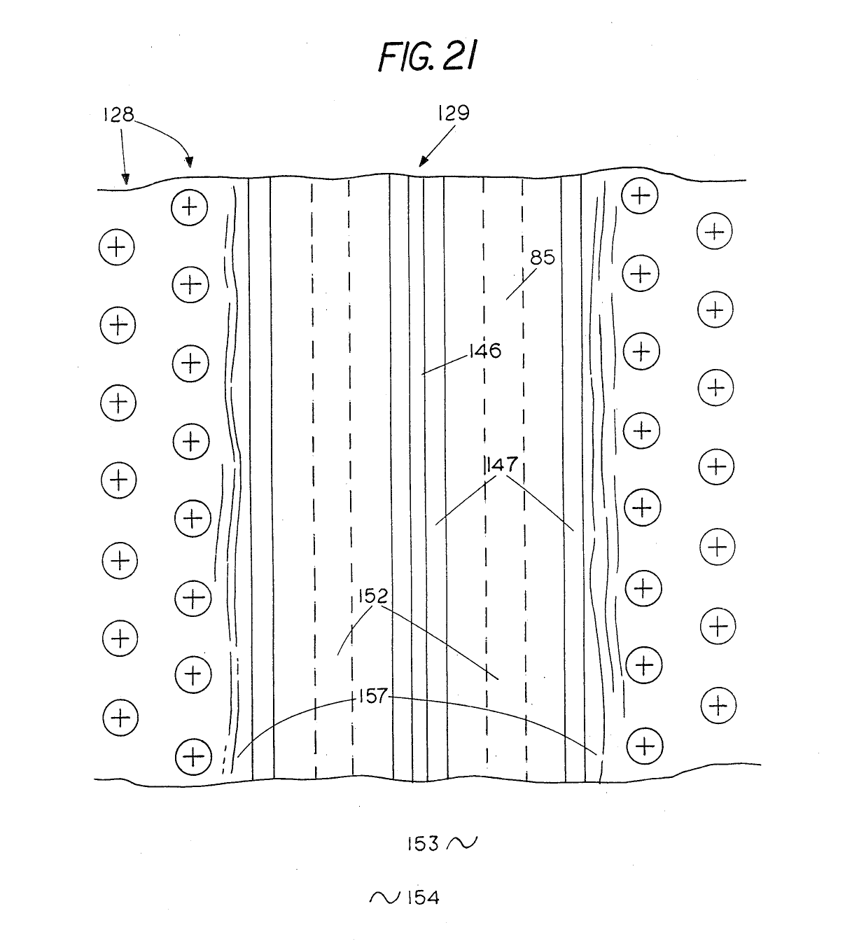

FIG. 21 is a top plan view of a section of interstate highway 129 showing one possible configuration of a plurality of artificial palm trees 29 consisting of solar arrays 30 positioned in staggered double rows 128 on each side of the highway 129. The solar arrays 30 have a structure configured to resemble natural foliage and can be linked together to create a network 153 of solar arrays 30 and a solar power grid 154. In FIG. 21, the opposite lanes 152 of the interstate highway 129 each have two shoulders 147, and are separated by a center divider or barrier 146. Further, the topography to the outside of both lanes 152 of the interstate highway 129 is characterized by gradually increasing vertical elevation and hills 157. Many other landscapes, topographical characteristics, and configurations are possible. As shown, the artificial palm trees 29 are positioned approximately thirty-two feet apart in each row 128, and the two rows 128 are also separated by thirty-two feet. Other dimensions can be used, as desired, but it can be advantageous to provide sufficient spacing to prevent substantial shading of adjacent solar arrays 30. The height, diameter, and composition of the artificial palm trees 29 can be varied, and other styles and types of artificial foliage consisting of alternative solar arrays can be used in synergistic combination with the artificial palm trees 129, or alternatively, with evergreen or deciduous trees, as may be desired. Accordingly, many combinations and permutations are possible. The ability to provide a large number of different combinations can be functional from the standpoint of optimizing power generation, and can also serve aesthetic purposes consistent with the best practices of engineering and landscape architecture.

Moreover, the present invention anticipates and teaches making various planning models for application to common road configurations regarding the installation of solar arrays, and also recharging stations. For example, various standardized models can be created for installations alongside relatively straight one mile stretches or other standard distances such as one kilometer stretches of two lane, divided two lane, divided four lane, divided three lane, and other common road and highway configurations. Appropriate models can also be made for various common intersections such as four way intersections, T shaped intersections, L shaped intersections, turnabouts, and various on and off ramp configurations associated with roads and highways. Accordingly, the planning for various installations can be made relatively fast and easy, and both the costs and electrical power generated by any selected set of options can be known with a great degree of certainty. A city, county, state, or federal planner, or an elected official such as a commissioner, mayor, governor, representative, or senator can then be empowered with accurate information for decision making concerning the installation of a network of solar arrays, recharging stations, and other devices and structures associated with a solar power grid.

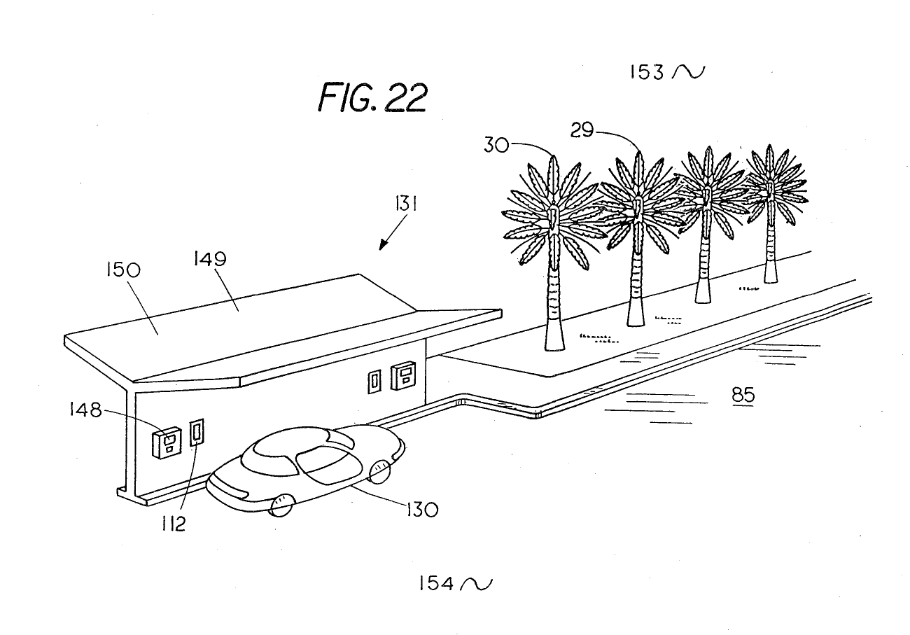

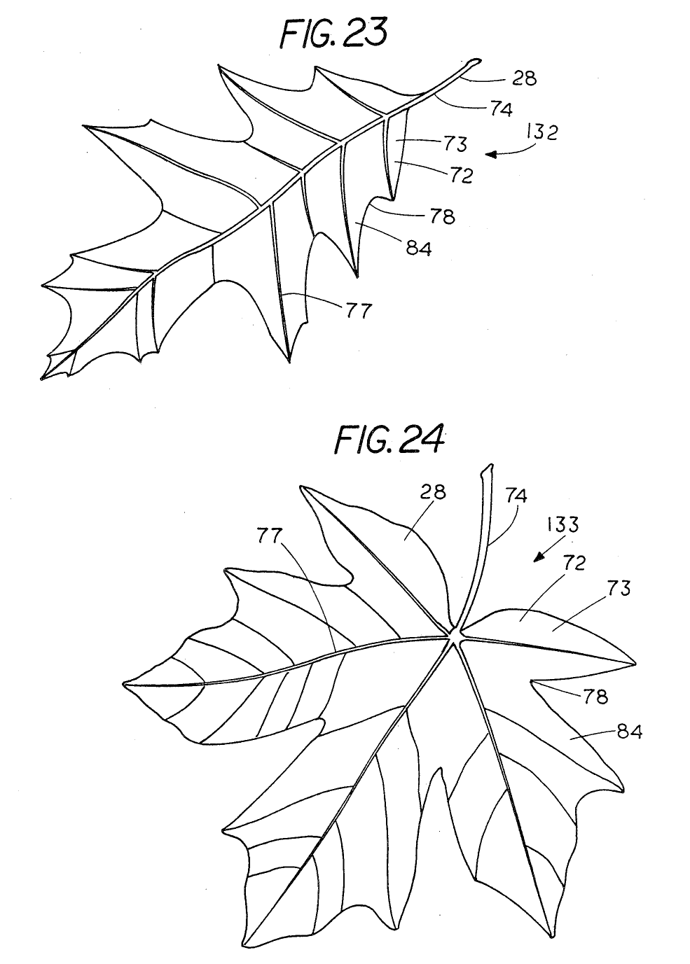

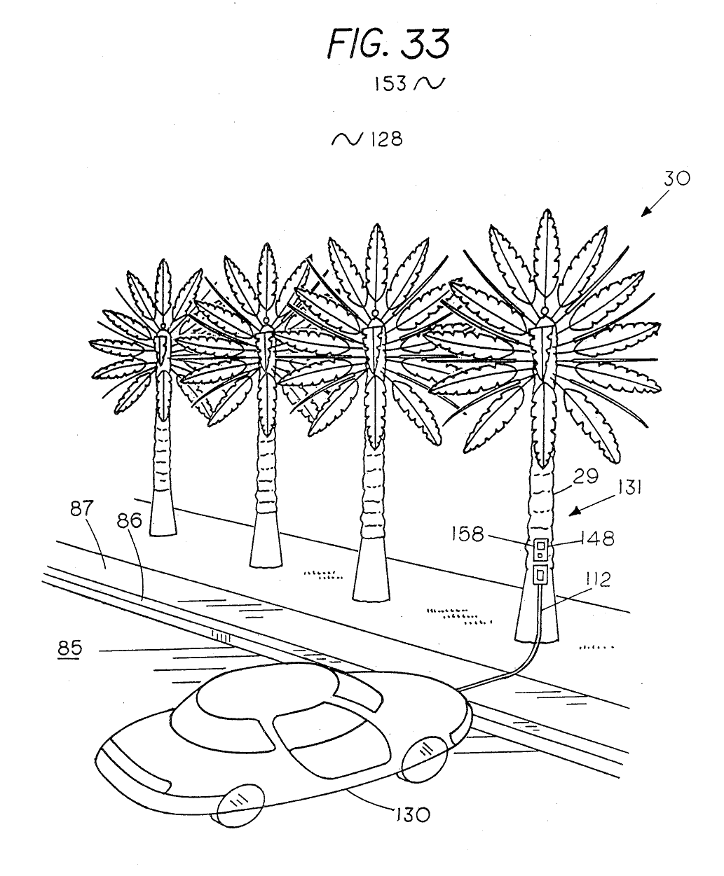

FIG. 22 is a perspective view of a transportation vehicle comprising an electric or hybrid automobile 130 that is parked at an electric recharging station 131 by the side of a street. In this regard, it can be readily understood that a transportation vehicle can also comprise an automobile, truck, bus, train, trolley car, bicycle, scooter, or motorcycle. The roof 150 of the recharging station can include conventional photovoltaic solar panels 149. Manufacturers of conventional photovoltaic solar panels 149 include Kyocera Solar, Inc. of Scottsdale, Arizona, Sharp Electronics Corporation, Inc. of Mahwah, N.J., Evergreen Solar of Marlboro, Mass., BP Solar of Linthicum, Md., and Shell Solar of Camarillo, Calif. The recharging station 131 can serve as an energy storage facility, and can be in communication with electrical energy and power which is produced by a network 153 of artificial palm trees 29 or other forms of artificial foliage which constitute solar arrays 30. The solar arrays 30 can line the sides of a parking lot area, or public transportation right of ways such as a street, or highway. The network 153 of solar arrays 30 and recharging station 131 can form or be in communication with one or more other solar power grids 154, and can also be coupled to one or more conventional power grids. As shown and discussed in FIG. 16 above, and also in FIG. 33 below, a solar array 30 can comprise a recharging station 131 and include mechanical means for making a direct connection with a transportation vehicle 130, including, but not limited to, an electric cord 112, or a conduit for the transmission of solid or fluid matter, and the like. Further, a recharging station 131 can provide one or more fully recharged energy storage devices, including, but not limited to, an electric battery, or capacitor, for making a rapid exchange with one or more energy storage devices present on a transportation vehicle which have been substantially depleted.

FIG. 23 is a top view of an artificial oak leaf 132 for use with an artificial deciduous oak tree 135 which consists of a solar array 30. The artificial oak leaf 132 can include a solar module 28 having at least one solar cell 73. As shown, the artificial oak leaf 132 can include a stem 74, a blade portion 84, notches 78 and veins 77.

FIG. 24 is a top view of an artificial maple leaf 133 for use with an artificial deciduous maple tree 136 which consists of a solar array 30. The artificial maple leaf 133 can include a solar module 28 having at least one solar cell 73. As shown, the artificial maple leaf 133 can include a stem 74, a blade portion 84, notches 78 and veins 77.

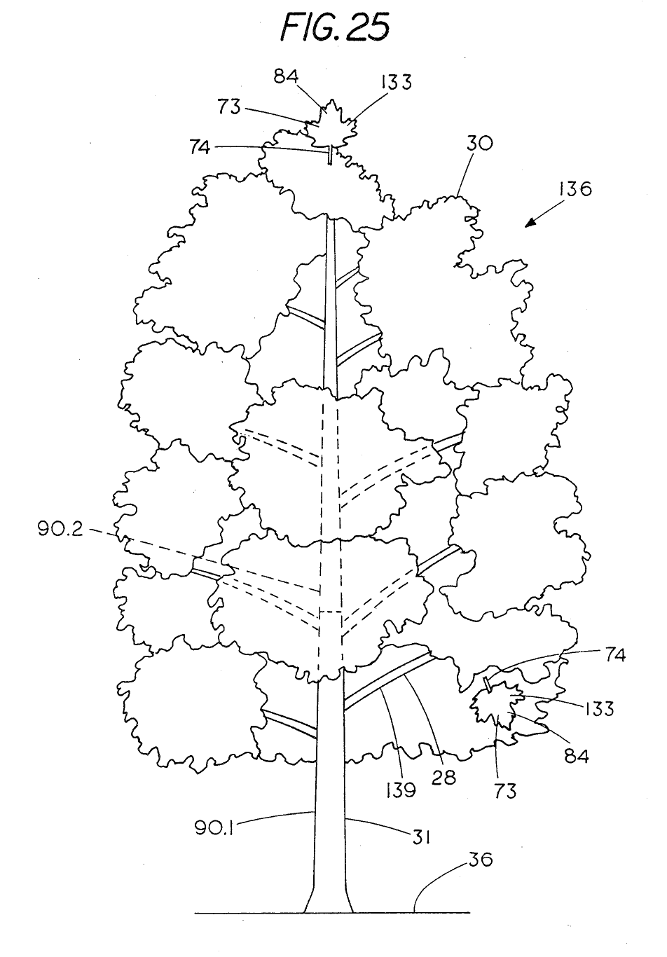

FIG. 25 is a side perspective view of an artificial deciduous maple tree 136 which consists of a solar array 30. The artificial maple tree 136 includes a trunk 31 and a plurality of artificial branches 139 which include a plurality of artificial maple leaves 133. Again, the artificial maple leaves 133 can include a solar module 28 having at least one solar cell 73. The trunk 31 can be made in a plurality of sections having different lengths such as sections 90.1 and 90.2, and the height of an artificial maple tree 136 can then be varied, as desired.

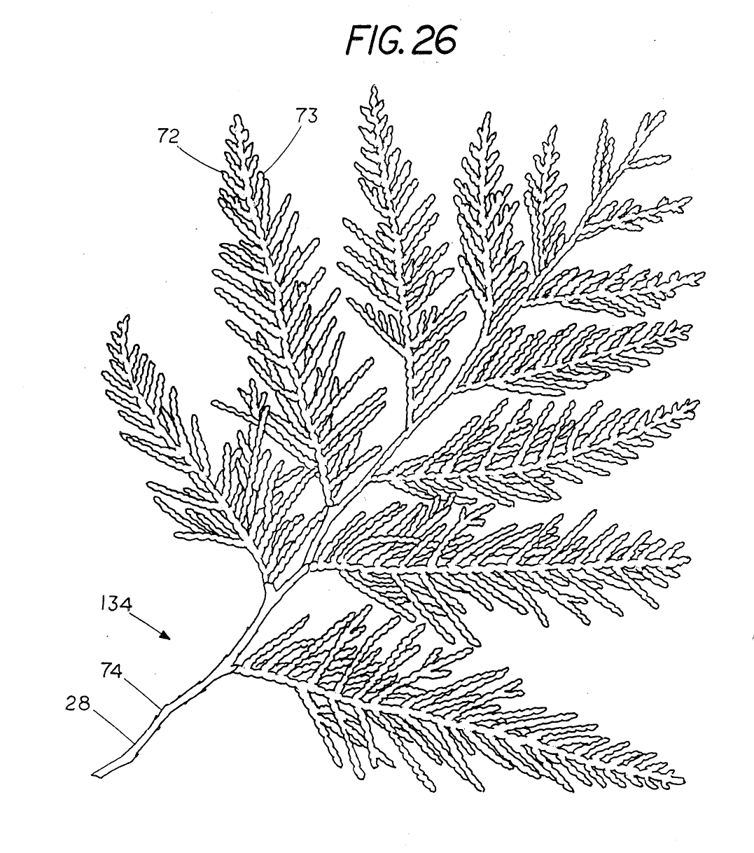

FIG. 26 is a perspective view of a portion of an artificial branch 139 including leaves 134 for use with an artificial evergreen tree 137 that consists of a solar array 30. The artificial leaf 134 can include a solar module 28 having at least one solar cell 73. As shown in FIG. 26, the branches 139 and leaves 134 can be made to resemble those of a western red cedar or sequoia. It is possible to use conventional molding and cutting techniques to make at least a portion of an artificial branch 139 including leaves 134.

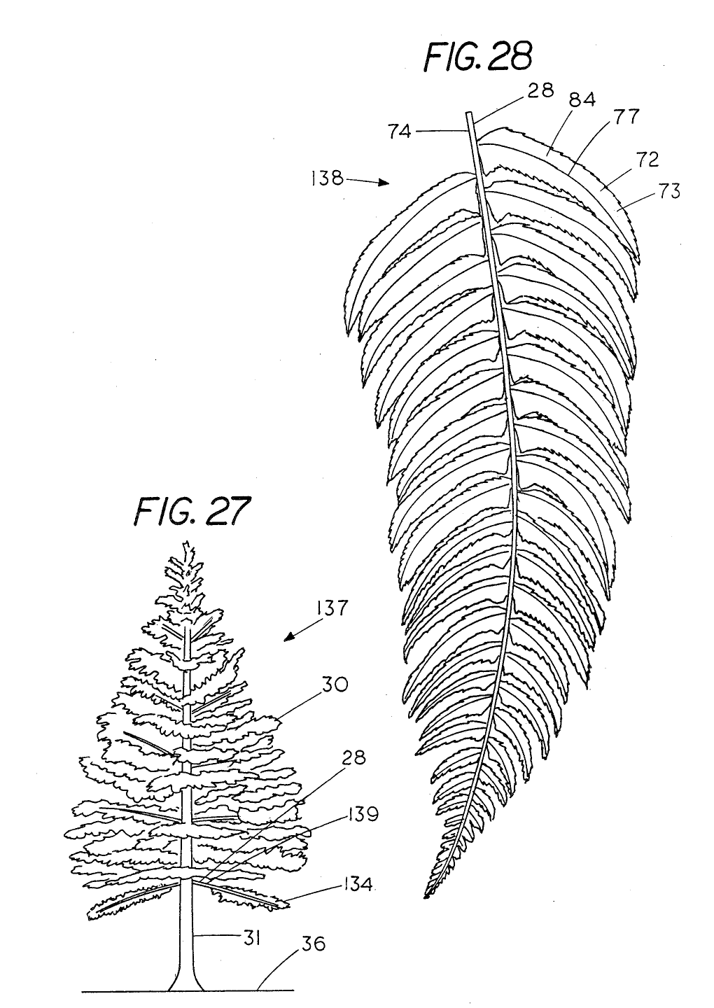

FIG. 27 is a side perspective view of an artificial evergreen tree 137 such as a western red cedar which consists of a solar array 30. The leaves or needles of the cedar tree and also sequoias are relatively planar, and in particular, when compared with the leaves or needles of many other evergreen trees. In this regard, the leaves or needles of a cedar tree have the appearance of having been pressed. Gravity then causes the leaves and branches of cedar trees to drape and take on a soft random feathered appearance. Because of the relatively planar configuration of their leaves, it is possible to made artificial branches and leaves 134 resembling those of the western red cedar and sequoia. The leaves 134 can include a solar module 28 including at least one thin-film solar cell 73, or alternatively one made by painting, or other coating process.

FIG. 28 is a top view of an artificial fern leaf 138 for making an artificial fern plant. The artificial fern leaf 138 can include a solar module 28 having at least one solar cell 73. As shown, the artificial fern leaf 138 can include a stem 74, a blade portion 84 including notches 78, and veins 77.

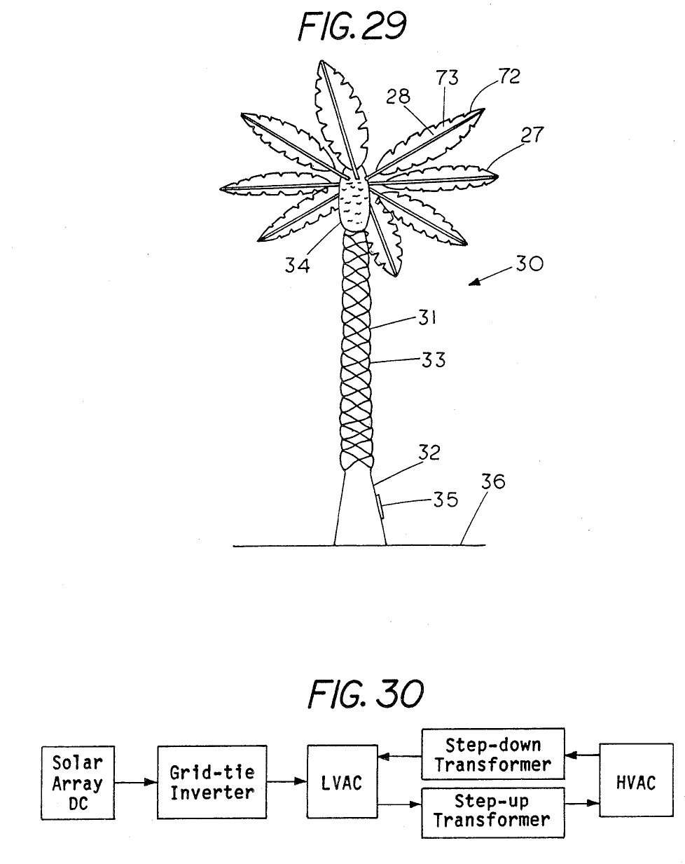

FIG. 29 is a side perspective view showing an artificial palm tree 29 which consists of a solar array 30. In this embodiment, the leaves or artificial palm fronds 72 can include a solar module 28 made of a relatively rigid material including monocrystalline silicon, polycrystalline silicon, crystalline gallium arsenide, and the like. The artificial palm fronds 72 can be relatively rigid and the solar modules 28 including at least one solar cell 73 can then be affixed to a relatively rigid substrate. In this regard, glass reinforced plastics, ceramics, or metal materials such as aluminum or stainless steel can be used. Using conventional photovoltaic solar cells 73 that are presently commercially available, the solar modules 28 and solar array 30 shown in FIG. 29 can have an efficiency of approximately 14-16 percent. However, given the status of current research and development efforts in the solar industry something exceeding 35 percent efficiency may be possible to achieve within the next decade. For example, Spectrolab of Sylmar, Calif., a subsidiary of The Boeing Company has achieved an efficiency of 36.9 percent with a photovoltaic cell. Given the commercial products available today, the efficiency of a solar cell made using a crystalline silicon material is then nearly three times that of one made using amorphous thin-film materials which commonly enjoy an efficiency of only 5-6 percent. However, the former solar cells are more expensive and less environmentally friendly to manufacture relative to the latter.

As shown in FIG. 29, a solar array 30 can have eight artificial palm fronds 72 including solar modules 28 each having a working area of 18 square feet. Accordingly, the solar array 30 has a total working area of about 144 square feet, or approximately two square meters. Given an efficiency of 15 percent, the solar array 30 will produce about 300 watt-hours, thus about 2.4 kilowatt-hours during an eight hour period. However, given an efficiency of 35 percent, such a solar array 30 would produce about 700 watt-hours, thus about 5.6 kilowatt-hours during an eight hour period. In comparison, the model discussed previously of a solar array made using some thirty-two artificial palm fronds including solar modules having solar cells consisting of an amorphous thin-film material, and in particular, R15-1200 Powerfilm ® made by PowerFilm, Inc. enjoyed a working surface area of 192 square feet and could produce 4.6 kilowatt-hours during an eight hour period.

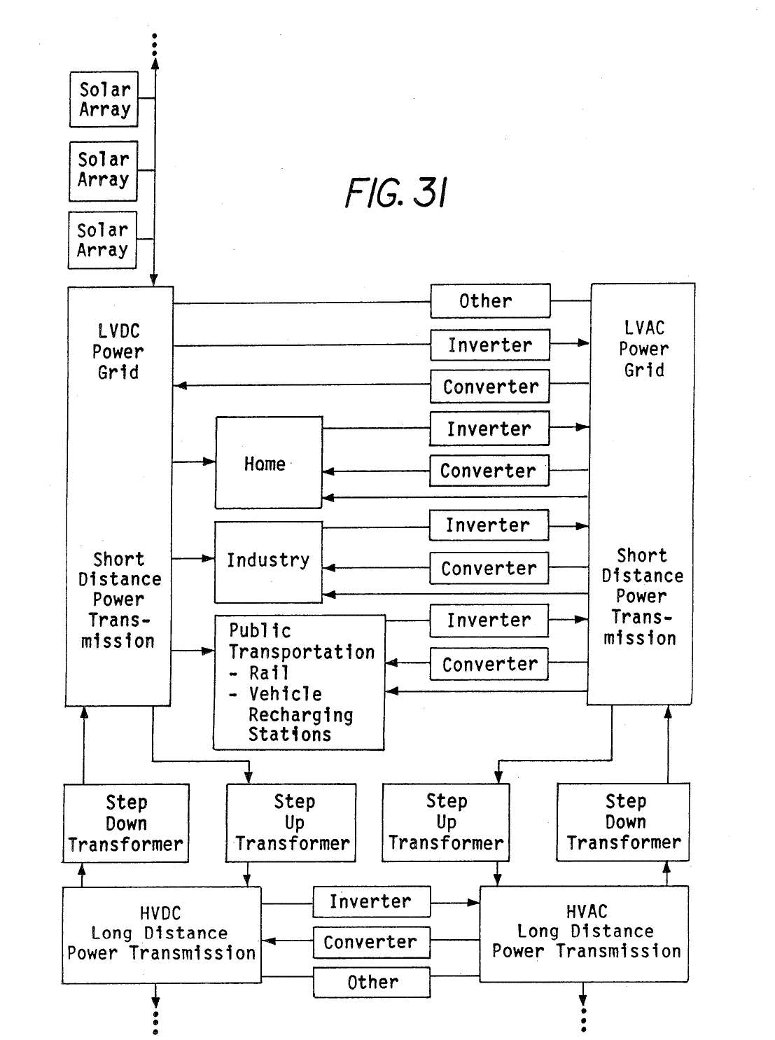

FIG. 30 is a flow diagram showing a solar array 30 linked to a grid-tie inverter for changing DC current to AC current, and then also to a low voltage AC (LVAC) power transmission line associated with a conventional AC power grid. The AC power grid can further include step-up transformers for creating high voltage AC (HVAC) current from low voltage AC current for long distance distribution. Further, the AC power grid can further include step-down transformers for converting high voltage AC power to low voltage AC power. Many other devices and means are also commonly used to generate and control electric power within a power grid, including but not limited to generators, capacitors, combiners, inductors, shot reactors, transformers, breakers, means for balancing power swings such as a static var compensator, thyristors, a thyristor-controlled series capacitor, and the like. Power coming into a residence in the United States is normally 120 volts (V) or 220 V AC at a frequency of 60 cycles per second, whereas local distribution lines commonly carry voltages of 6.9 kilovolts (kV), 13.8 kV, 27.6 kV, 44 kV, and high voltage AC transmission lines can be at 115 kv, 230 kV, or 500 kv.

FIG. 31 is a flow diagram showing a network of solar arrays which form at least a portion of a solar power grid. As shown, the solar arrays can transmit power using low voltage DC (LVDC) lines. The DC solar power grid can be linked to an AC power grid. Inverters can be used to change DC to AC current, and converters can be used to change AC to DC current. Step-up transformers can be used to change low voltage DC current to high voltage DC current (HVDC), or low voltage AC current (LVAC) to high voltage AC current (HVAC). Conversely, step-down transformers can be used to change HVDC to LVDC, or HVAC to LVAC. Many other devices and means are also commonly used to generate and control electric power within a power grid. Given the technology which is available at the present time and at distances greater than 500 miles, high voltage DC power is less expensive to transmit than high voltage AC power. Low voltage DC power can generally be transmitted as inexpensively as AC power for a distance of 50 km when buried underground, and also for a distance of 600-800 km when transmitted by overhead power lines. If the power being produced by the solar arrays will primarily be used locally, then the use of low voltage DC power can indeed be efficient. Various DC combiners and converters can be used with a DC solar power grid. Further, it is anticipated that low voltage DC power created by a network including a plurality of solar arrays can be changed using a step-up transformer to create high voltage DC (HVDC) current which can be efficiently transmitted long distances using superconductors.

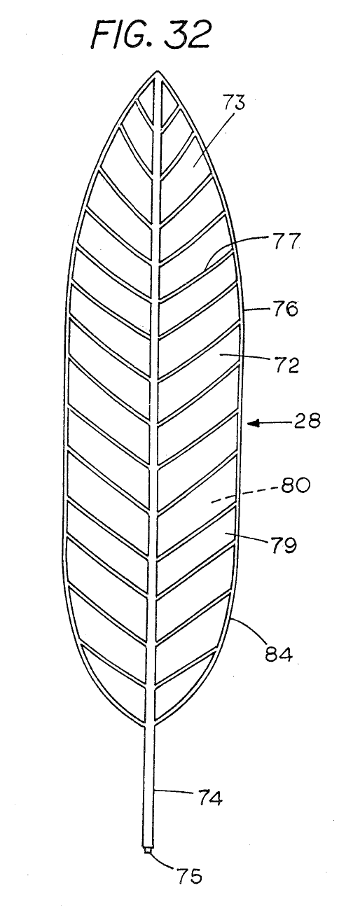

FIG. 32 is a top plan view of an artificial palm frond 72 including a stem portion 74 and also a blade portion 84 having smooth edges.

FIG. 33 is a top perspective view of a transportation vehicle 130 connected with the use of hard wiring, and in this case, a recharging cord 112 to a solar array 30 having an integral recharging station 131 including a vending machine device 148. The vending machine device 148 can accept payment, e.g., in the form of cash, credit card, debit card, voucher, or ticket for different provided and/or selected quantities of electric power, and thereby permit recharging of the means for storing electric power on the transportation vehicle, including, but not limited to, an integral or removable storage device such as a battery 97, or capacitor. A solar array or network of solar arrays can be included in parking areas, lots, but also parking structures.

An example of a parking lot located in Europe that provides conventional wired recharging stations is disclosed in the article “Recharging electric cars with solar panels, the first in Europe,” by Automotive, Dec. 30, 2009, http://www.auto-car-shop.com/15112/recharging-electric-cars-with-solar-panels-the-first-in-europe.

### Remote Wireless Charging and Powering of Electrical Devices and Transportation Vehicles

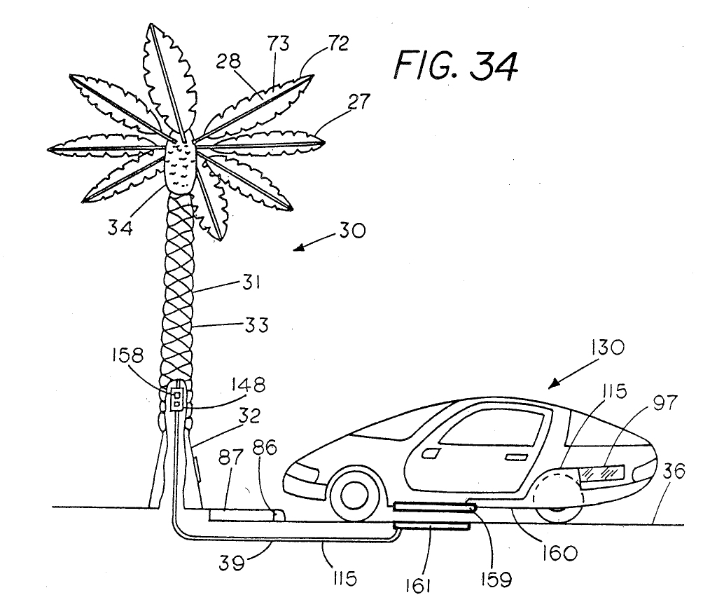

FIG. 34 is a side view illustration with some parts broken away of a transportation vehicle 130 including a wireless receiver device 159 on a lower surface 160 positioned over a wireless transmission device 161 which is located on the underlying support surface 36 and electrically coupled and possibly hard wired to a solar array 30 resembling a palm tree. Accordingly, the wireless receiver device 159 can be positioned in functional relation and electrically coupled to the wireless transmission device 161, thus permitting the recharging of the means for storing electrical energy and power on a transportation vehicle such as an energy storage device, including, but not limited to, a battery 97, or capacitor. In this regard, the transportation vehicle can include an integral or removable energy storage device. Again, a solar array or network of solar arrays comprising a wireless transmission device 161 can be included in parking lot areas, but also parking structures.

Accordingly, the present invention teaches and shows solar arrays resembling natural foliage, e.g., palm trees, which produce energy and can comprise wireless transmission devices adapted to provide energy to electronic devices, electrical appliances and devices, and transportation vehicles. This energy can be in the form of energy associated with the electromagnetic spectrum which includes gamma ray energy, x-ray energy, ultraviolet light energy, visible light energy, infrared energy, microwave energy, radar energy, radio frequency energy, electrical energy, television signal energy, and telephone signal energy. In particular, the present invention teaches solar arrays resembling natural foliage including wireless transmission devices adapted to provide electrical energy to electric or hybrid transportation vehicles. Accordingly, when a network of solar arrays resembling palm trees are placed in functional relation and proximity to electric or hybrid transportation vehicles, the network of solar arrays and wireless transmission devices can be used to recharge and/or actively power stationary and/or moving electric or hybrid transportation vehicles in parking lot areas, or structures, and also in public transportation right of ways such as roads, and highways. A more detailed disclosure and discussion of wireless transmission devices and also wireless receiver devices which can be suitable for use is provided below.

At this time, several automobile manufacturers are making hybrid or electric vehicles: e.g., see www.teslamotors.com as of Aug. 29, 2011 for information on Tesla electric vehicles; www.toyota.com as of Aug. 29, 2011 for information on the plug-in Toyota Prius; www.nissanusa.com as of Aug. 29, 2011 for information on the Nissa Leaf electric vehicle; and, www.chevrolet.com as of Aug. 29, 2011 for information of the Chevy Volt. Further, several different companies are working on or in the process of commercializing devices which enable the remote wireless charging of electric transportation vehicles and other electronic devices. Some of the methods and devices being employed include the use of magnetic inductance, magnetically coupled resonance, and radio frequency.

For example, Halo IPT, in New Zealand, which is associated with Professor John Boys is working on remotely powering and charging electric vehicles, e.g., as disclosed on the website www.haloipt.com as of Aug. 29, 2011, and the article “Ditch the Cord, Let the Road Charge Your EV,” by Keith Barry, Nov. 22, 2010, http://wired.com/autopia/2010/11/ditch-the-cord-let-the-road-charge-your-ev. Halo IPT is presently able to get 7 Kw across a 300 mm gap, and 3 Kw across a 400 mm with an efficiency in the range between 85-98% for the entire system. Boys is associated with a large number of patent applications and patents including, e.g., the following published U.S. patent applications, 20090129126, 20090302688, 2010019604, 20100289340, 20110105020, and 20110116290, and also, the following issued U.S. Patents, U.S. Pat. No. 4,295,189, U.S. Pat. No. 4,563,630, U.S. Pat. No. 4,881,022, U.S. Pat. No. 5,126,585, U.S. Pat. No. 5,293,308, U.S. Pat. No. 5,450,305, U.S. Pat. No. 5,528,113, U.S. Pat. No. 5,619,078, U.S. Pat. No. 5,821,638, U.S. Pat. No. 5,898,579, U.S. Pat. No. 5,969,497, U.S. Pat. No. 6,020,658, U.S. Pat. No. 6,100,663, U.S. Pat. No. 6,188,179, U.S. Pat. No. 6,483,202, U.S. Pat. No. 6,621,183, U.S. Pat. No. 6,705,441, U.S. Pat. No. 6,903,532, U.S. Pat. No. 7,279,850, U.S. Pat. No. 7,474,062, U.S. Pat. No. 7,633,235, U.S. Pat. No. 7,781,916, U.S. Pat. No. 7,969,269, the complete contents of all these recited patent applications and issued patents being hereby incorporated by reference herein.

A large auto parts company having the name Delphi and also Toyota Motors are teaming up with the company WiTricity that was founded by several individuals associated with MIT. In particular, the company is associated with the work of Assistant Professor Marin Soljacic who is named on a large number of patents on the subject, as disclosed on the website www.witricity.com as of Aug. 29, 2011, and also the articles “Wireless Car Charging.Net The Next Generation of Motion” on the webpage, http://www.wirelesscarcharging.net, and “Wireless Electricity Is Here (Seriously)” by Paul Hochman, Jan. 6, 2009, in FastCompany.com: http://www.fastcompany.com/magazine/132/brilliant.html. In particular, Soljacic is named as an inventor on two issued U.S. patents, namely, U.S. Pat. No. 7,741,734, and U.S. Pat. No. 7,825,543, but also on the following published and still pending U.S. patent applications: 2011069339, 20110162895, 20110148219, 20110140544, 20110074347, 20110074346, 20110074218, 20110049998, 20110049996, 20110043049, 20110043048, 20110043047, 20110043046, 20110025131, 20110018361, 20110012431, 20110002574, 20100327661, 20100327660, 20100277005, 20100264745, 20100259108, 20100253152, 20100237708, 20100237707, 20100237706, 20100231053, 20100225175, 20100219694, 20100207458, 20100201205, 20100187911, 20100181844, 20100171370, 20100171368, 20100164298, 20100164297, 20100164296, 20100148589, 20100141042, 20100133920, 20100133919, 20100133918, 20100127575, 20100127574, 20100127573, 20100123355, 20100123354, 20100123353, 20100117456, 20100117455, 20100109445, 20100102641, 20100102640, 20100102639, 20100096934, 20090284083, 20090267710, 20090267709, 20090224856, 20090195333, 20090195332, 20080278264, the complete contents all of these recited U.S. patents and patent applications being hereby incorporated by reference herein.

Fulton Innovation, LLC. in Michigan is associated with Bret Lewis and a pad based system called eCoupled, and this company also has over 600 patents relating to wireless power transmission as discussed on the website www.fultoninnovation.com, and www.wirelesspowerconsortium.com, as of Aug. 29, 2011. In particular, Fulton Innovation, LLC. is presently associated with U.S. Pat. No. 6,975,198, U.S. Pat. No. 7,126,450, U.S. Pat. No. 7,212,414, U.S. Pat. No. 7,233,222, U.S. Pat. No. 7,385,357, U.S. Pat. No. 7,462,951, U.S. Pat. No. 7,518,267, and U.S. 7,522,878, the complete contents all of these recited patents being hereby incorporated by reference herein. Further, the company has demonstrated inductive recharging of a Tesla Roadster electric vehicle.

Ryan Tseng of WiPower in Altamonte Springs, Florida has created an induction system, and he is associated with two pending U.S. patent applications which have been published, i.e., 20080067874, and 20110133570, and the complete contents of these two patent applications are hereby incorporated by reference herein.

A company named Powercast in Pittsburg, Pa. makes a radio frequency remote power system, sells wireless Christmas ornaments and is testing industrial sensors, as disclosed on the website www.powercastco.com, as of Aug. 29, 2011.

Solar Roadways has obtained a grant from the U.S. Department of Transportation to include solar panels into roadway surfaces and to then transmit the power to electric vehicles as disclosed on the website www.solarroadways.com, and the article “Will Solar Roads Change Electric Cars?” by Team Planet Green, Oct. 13, 2010, PlanetGreen.com, planetgreen.discovery.com/tech-transport/will-solar.

Nissan has a wireless EV charging station at Google headquarters which was made by Plugless Power which is based in Virginia as disclosed on the website www.pluglesspower.com as of Aug. 29, 2011, and also in the following articles: “Google Installs Wireless EV Charging Station,” by Keith Barry, Mar. 21, 2011, http://wired.com/autopia/2011/03/google-installs-a-wireless-ev-charging-station/; “Nissan's plug-free electric car” by Bibi van der Zee and Adam Vaughan, Jul. 20, 2009, guardian.co.uk, www.guardian.co.uk/.../jul/20/nissan-electric-car-plug-free; “EV charging station recharges without wires,” by Liane Yvkoff, Jul. 29, 2010, CNET Reviews, http://reviews.cnet.com/8301-13746-7-20012101-48.html?tag=mncol;txt; and, “How Far Off is Wireless Electric Car Charging?” by Team Planet Green, Oct. 19, 2010, PlanetGreen.com, planetgreen.discovery.com/tech-transport/how-far-off-is.

BMW is now teaming with Siemens to provide wireless charging of electric vehicles as disclosed in the article “BMW and Siemens partnering for wireless-charging EVs, cutting the cord this May,” by Tim Stevens, Apr. 14, 2011, http://engadget.com/2011/04/14/bmw-and-seimens-partnering-for-wireless-charging-electric-vehicles.

Volvo is also providing for inductive recharging of electric vehicles as disclosed in the article “Volvo working on wireless charging for EVs,” by Liane Yvkoff, May 20, 2011, CNET Reviews, http://reviews.cnet.com/8301-13746_{—}7-20064771-48.html.

In brief, wireless recharging or powering of electric vehicles is presently being implemented and provided by automobile manufacturers. Moreover, the present work of Professor Boys at Halo IPT in New Zealand, and also that of Assistant Professor Soljacic at MIT and the company WiTricity can provide the ability to recharge and / or power electric vehicles at some distance, and also while the transportation vehicles are in motion.

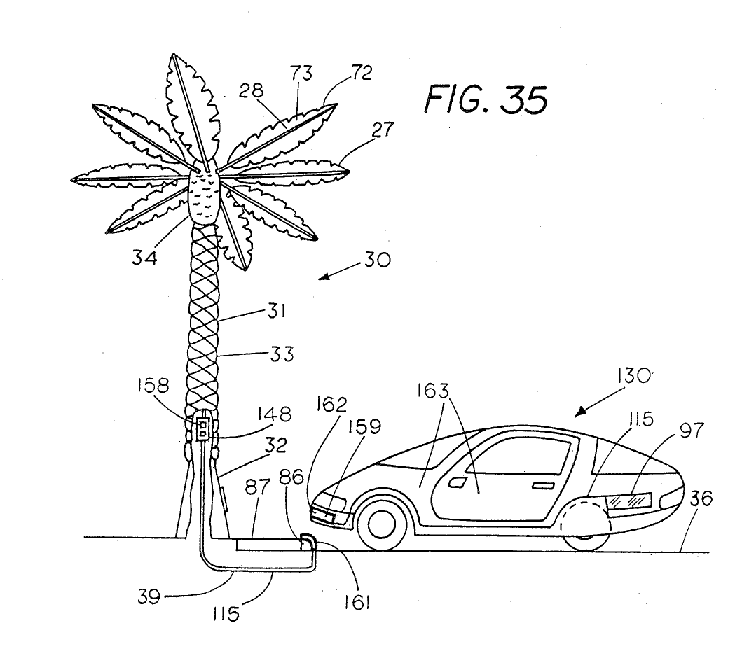

FIG. 35 is a side view illustration with some parts broken away of a transportation vehicle 130 including a wireless receiver device 159 on a front surface 162 positioned adjacent to a wireless transmission device 161 which is electrically coupled and possibly hard wired to a solar array 30 resembling a palm tree 29 and positioned on a curb 86. Accordingly, the wireless receiver device 159 can be positioned in functional relation and electrically coupled to the wireless transmission device 161, thus permitting the recharging of the means for storing electric power on the transportation vehicle, including, but not limited to, a battery 97, or capacitor. Accordingly, it can be readily understood that the transportation vehicle can include an integral or removable energy storage device.

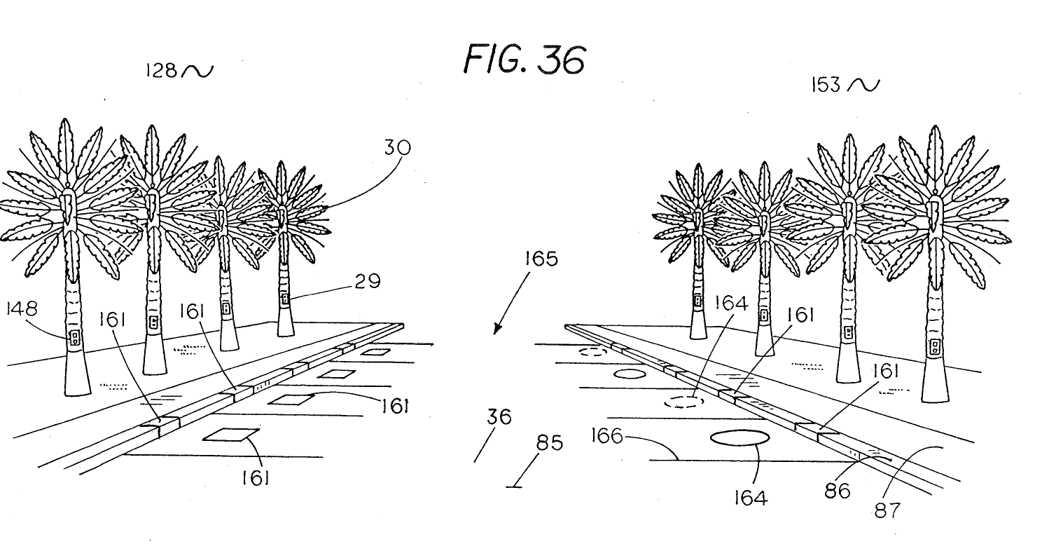

FIG. 36 is a side perspective view showing a plurality of wireless repeater devices 164 located on a horizontal support surface 36 in a parking lot, 165 having individual parking spaces indicated by lines 166. The wireless repeater devices 164 are electrically coupled to at least one solar array 30 including means for wireless communication and transmission of electric power. This can include a wireless transmission device 161 positioned, e.g., on a curb 86 or horizontal support surface 36 which is electrically coupled, and possibly by hard wiring, to a vending machine device 148. Shown on the left of FIG. 36 is a plurality of wireless transmission devices 161 positioned on both the curb 86, but also on the horizontal support surface 36 within each parking spot which are electrically coupled and possibly hard wired to at least one solar array 30 in order to accommodate transportation vehicles 130 having wireless receiver devices 159 located on either their front surface 162 or lower surface 160. Shown on the right of FIG. 36 is a plurality of wireless transmission devices 161 positioned on the curb 86 which are electrically coupled and possibly hard wired to at least one solar array 30 in order to accommodate transportation vehicles 130 having wireless receiver devices 159 located their front surfaces 162, but also a plurality of wireless repeater devices 164 positioned on a horizontal support surface 36 which are remotely electrically coupled to the wireless transmission devices 161 in order to accommodate transportation vehicles 130 having wireless receiver devices 159 located on their lower surfaces 160. It can be readily understood that the wireless transmission devices and repeater devices can be similarly employed in an alternative parking area, such as a parking ramp, or parking structure.

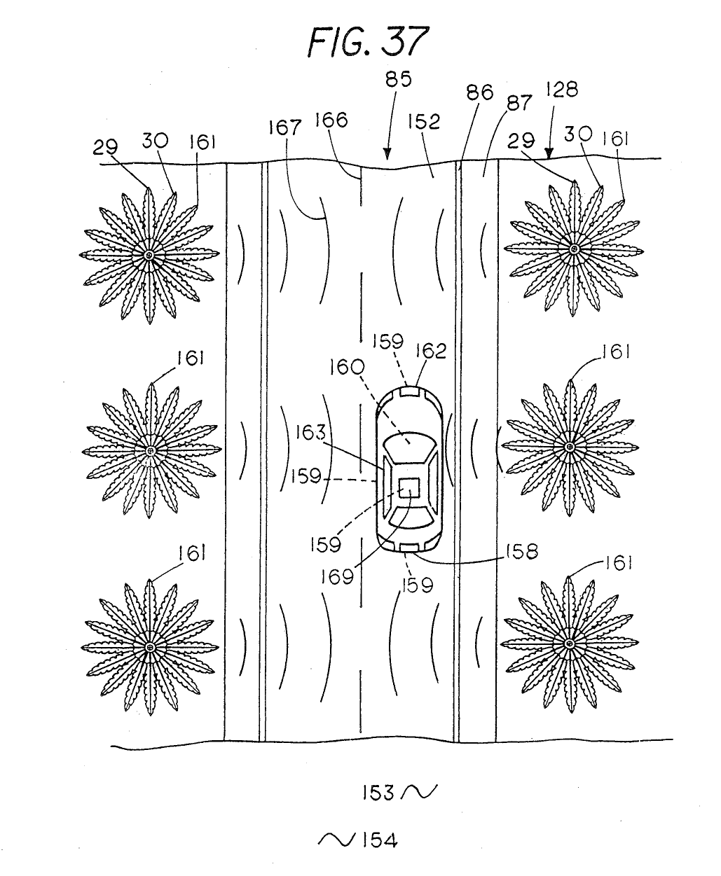

FIG. 37 is a top plan view showing a network of solar arrays 153 resembling palm trees 29 including means for wireless communication and transmission of electric power, such as wireless transmission devices 161, being located alongside both sides a street 85, and also a transportation vehicle 130 in motion. As shown, the transportation vehicle 130 can have at least one wireless receiver device 159 on one or more of the front surface 162, back surface 168, top surface 169, lower surface 160, or side surfaces 163 for electrically coupling with at least one wireless transmission device 161 which is electrically coupled with at least one solar array 30. Alternatively, the network of solar arrays 153 could extend along only one side of a street 85.

### Repeater Devices for Extending the Range of Wireless Transmission

In order to increase the efficiency of the wireless transmission of electrical energy, and also the recharging of energy storage devices such as batteries, or capacitors which may be included upon a transportation vehicle, and in order to extend the effective range of wireless power transmission devices at least one repeater, resonator, or so-called range expander device can also be used. These repeater devices can be located at suitable distances for electrical coupling in parking lot areas, or along public transportation right of ways such as roads and highways. In some cases, wireless transmission devices, repeaters, resonators or range expanders can be positioned between or across the lanes of a public transportation right of way such as a railway, street, or highway.

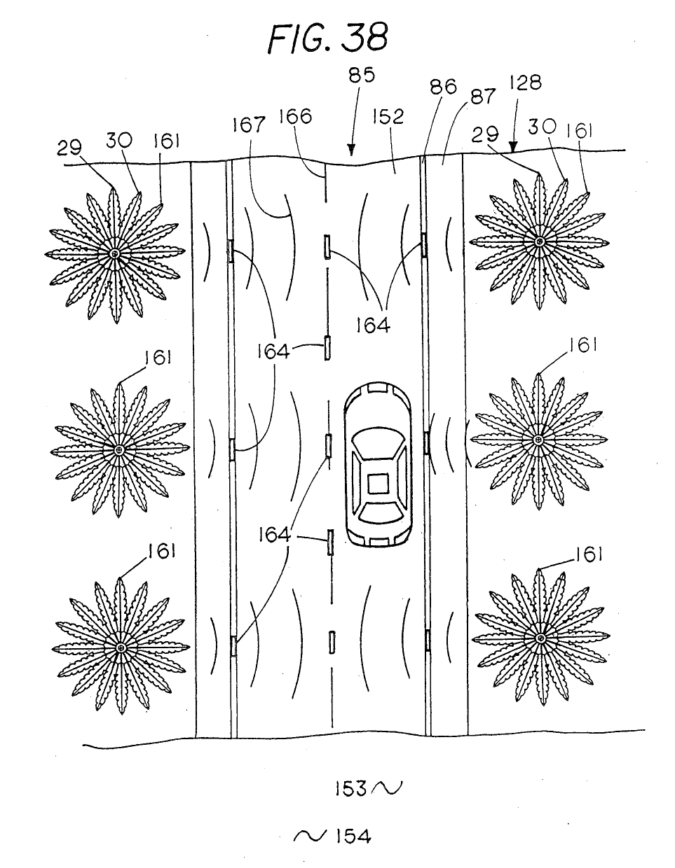

FIG. 38 is a top plan view similar to FIG. 37 showing a network of solar arrays 153 resembling palm trees 29 including means for wireless communication and transmission of electric power, such as wireless transmission devices 161, being located alongside both sides of a street 85, but also a plurality of wireless repeater devices 164. The wireless transmission devices 161 are electrically coupled with a plurality of wireless repeater devices 164 on or near the street 85, and also a transportation vehicle 130 in motion. As shown, the transportation vehicle 130 can have at least one wireless receiver device 159 on one or more of the front surface 162, back surface 168, top surface 169, lower surface 160, or side surfaces 163 for electrically coupling with at least one wireless transmission device 161 electrically coupled with at least one solar array 30, and also with at least one of the wireless repeater devices 164 located on or near the street 85. Alternatively, the network of solar arrays 153 could extend along only one side of a street 85.

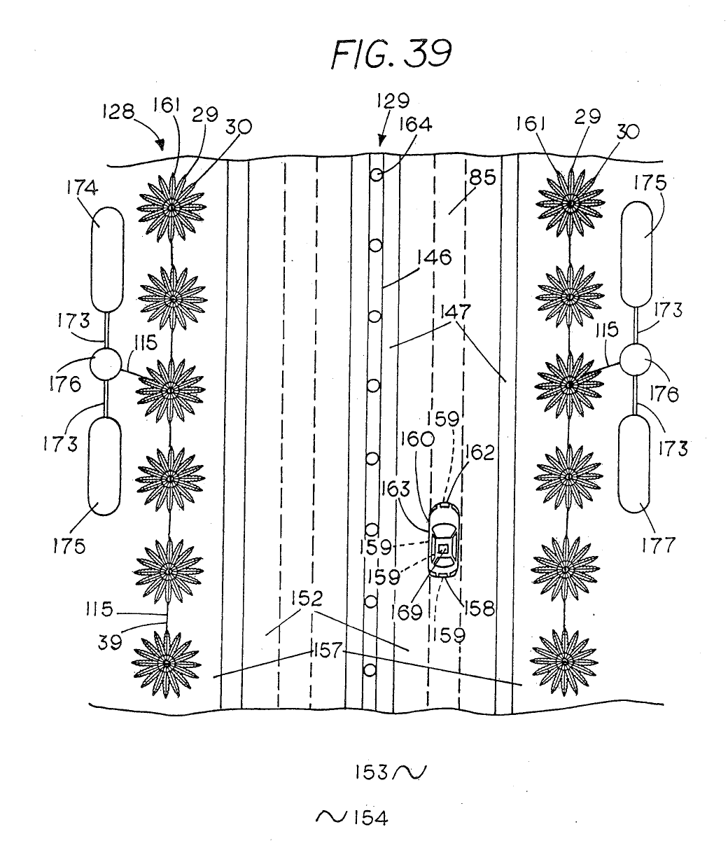

FIG. 39 is a top plan view showing a network of solar arrays 153 resembling palm trees 29 including means for wireless communication and transmission of electric power, such as wireless transmission devices 161, being located alongside a highway 129 and electrically coupled with a plurality of wireless repeater devices 164 on a centerline barrier and divider 146. The wireless transmission devices 161 are electrically coupled with a plurality of wireless repeater devices 164 on a centerline barrier and divider 146, and also a transportation vehicle 130 in motion. Again, the transportation vehicle 130 can have at least one wireless receiver device 159 on one or more of the front surface 162, back surface 168, top surface 169, lower surface 160, or side surfaces 163 for electrically coupling with at least one wireless transmission device 161 electrically coupled with at least one solar array 30, and also with at least one of the wireless repeater devices 164.

### Electrolysers for Water Purification and Hydrogen Production

Further, solar arrays resembling natural foliage, e.g., palm trees, of the present invention can produce electric power for powering electrolysers for purifying and/or de-salinating water when the solar arrays are coupled in functional relation with at least one suitable electrolyser device, e.g., such as one made by Global Energy Technology, Inc., a Puerto Rico Corporation having a mailing address of P.O. Box 90756, Long Beach, Calif. 90809, and website: http://get-inc.com as of Aug. 28, 2011, and phone (787) 303-0090, or General Electric having a webpage: http://www.ge.com and http://ecomagination.com/portfolio/desalination as of Aug. 28, 2011, and a phone (203) 373-2211.

Moreover, solar arrays resembling natural foliage, e.g., palm trees, of the present invention can produce electric power for powering electrolysers for making hydrogen fuel such as those made by Hydrogenics Coporation of 200 Admiral Boulevard, Mississauga, Ontario, Canada, L5T 2N6, having a website: http://www.hydrogenics.com as of Aug. 28, 2011, and a phone: (905) 361-3660. The hydrogen fuel can then be used for powering, e.g., transportation vehicles, homes, businesses, and also industrial use.

Also shown in FIG. 39 is the possible electrical coupling of a network of solar arrays 153 with at least one electrolyser device 176. On the left side of FIG. 39, a electrolyser device 176 is shown electrically coupled to the network of solar arrays 153 and positioned between and connected by pipes 173 to both a dirty/salt water storage tank 174 and also a clean water storage tank 175 the water contents of which have been purified by the electrolyser device 176. In this regard, solar arrays resembling natural foliage, e.g., palm trees, of the present invention can produce electric power for powering electrolysers for purifying and/or de-salinating water when the solar arrays are coupled in functional relation with at least one suitable electrolyser device, e.g., such as one made by Global Energy Technology, Inc., a Puerto Rico Corporation having a mailing address of P.O. Box 90756, Long Beach, Calif. 90809, and website: http://get-inc.com as of Aug. 29, 2011, and phone (787) 303-0090, or General Electric having a webpage: http://www.ge.com and http://ecomagination.com/portfolio/desalination as of Aug. 29, 2011, and a phone (203) 373-2211.

On right side of FIG. 39, a electrolyser device 176 is shown electrically coupled to the network of solar arrays 153 and positioned between and connected by pipes 173 to a clean water storage tank 175 and a hydrogen storage tank 177 the contents of which have been produced by the electrolyser device 176. Accordingly, it can be readily understood that solar arrays resembling natural foliage, e.g., palm trees, of the present invention can produce electric power for powering electrolysers for making hydrogen fuel such as those made by Hydrogenics Coporation of 200 Admiral Boulevard, Mississauga, Ontario, Canada, L5T 2N6, having a website: http://www.hydrogenics.com as of Aug. 29, 2011, and a phone: (905) 361-3660. The hydrogen fuel can then be used for powering, e.g., transportation vehicles, homes, businesses, and also industrial use.

### Antennas, Cell Towers, and Other Communications Devices

FIG. 40 is a side view of a solar array 30 resembling a palm tree 29 with parts broken away to show the inclusion of an antenna 170. The antenna 170 can be used to receive and/or transmit, e.g., radio communication, television signals, and other wireless communication. Moreover, it can be readily understood that when a solar array 30 resembling natural foliage such as a palm tree 29 has a structure including metallic components such as a support pole 38 which may be coupled to a plurality of artificial palm fronds 72 also including metallic stems 74, that a large portion of the solar array 30 can form and function as an antenna and at least a portion of a communications device.

FIG. 41 is a side view of a solar array 30 resembling a palm tree 29 with parts broken away to show the inclusion of a plurality of rectangular shaped cell tower communications devices 171, e.g., antennas, relays, or repeaters, and the like. As shown, the solar array 30 can also include an antenna 170 for receiving and/or transmitting radio communication, television signals, and other wireless communication. Again, it can be readily understood that when a solar array 30 resembling natural foliage such as a palm tree 29 has a structure including metallic components such as a support pole 38 which may be coupled to a plurality of artificial palm fronds 72 also including metallic stems 74, that a large portion of the solar array 30 can form and function as an antenna and at least a portion of a communications device. The solar array 30 can consist of a stand alone unit and be completely independent, or be electrically coupled to at least one other solar array 30 to form a network of solar arrays 30 and an independent solar power grid. Alternatively, one or more of solar arrays 30 can be tied to a conventional power grid.

However, a solar array 30 resembling natural foliage such as a palm tree can produce electric power which would enable an antenna 170, and/or cell tower communication device 171, e.g., an antenna, relay, repeater, to continue to function if and when a conventional electric power grid would fail, as could happen as the direct result of a natural disaster such as an earthquake or flood. In this regard, a solar array 30 resembling natural foliage such as a palm tree 29 can provide the electrical energy to continuously power radio, internet, telephone, television, and other vital communications equipment during the day, and also at night provided that it is electrically coupled with means for storage of at least some of the electric energy being produced during the daylight hours. Suitable electrical energy storage devices include, but are not limited to, e.g., a battery, capacitor, and the like. Accordingly, a network of solar arrays resembling natural foliage can provide a certain redundancy and an emergency backup system in the event of a natural disaster and possible failure of the conventional power grid.

### Solar Palm Tree Cost/Benefit Analysis

In an embodiment of the present invention, an artificial palm tree consisting of a solar array can be created by using between five and forty artificial palm fronds, although a greater or lesser number of artificial palm fronds can be used, as desired.

### Low Efficiency Model

For the purpose of providing a non-limiting simple example concerning the performance of such a solar array made with a thin film material having a relatively low efficiency in the range between 5-6%, a model can be constructed using photovoltaic thin film made by PowerFilm, Inc. A total of thirty-two artificial palm fronds can be arranged in four staggered layers with each layer including eight artificial palm fronds. The artificial palm fronds can have a stem approximately one and one half feet long. The working surface of the blade portion of each of the artificial palm fronds can measure approximately one foot by six feet, thus providing an area of six square feet. Accordingly, the total working surface area of the artificial palm tree model can consist of 192 square feet.

The resulting solar array can produce significant amounts of electrical power. In particular, each artificial palm frond including a R15-1200 Powerfilm ® module made by PowerFilm, Inc. operates at 15.4 volts and produces 1.2 amps. Multiplying the volts times the amps yields 18.48 watt-hours of power, and then multiplying the rounded off 18 watt-hours by eight hours of sunlight yields 144 watt-hours per day for each artificial palm frond. Further, multiplying 144 watt-hours by thirty two fronds yields 4.6 kilowatt-hours per day for a single artificial palm tree consisting of a solar array. If and when there would be more than eight hours of sunlight, or when the artificial palm fronds would be larger in size, or when an additional thirty two R15-1200 Powerfilm ® modules would be affixed to the bottom side of the artificial palm fronds as well, then the amount of power generated in a single day would be increased over and above the 4.6 kilowatt-hours per day.

A large portion of the Southwest region of the United States averages between six and seven hours of peak solar exposure or so-called “full sun hours” during the day, and the peak solar exposure in desert regions located closer to the equator is even greater. The sun's power or irradiance peaks at about 1,000 watts per square meter per hour. Most commercially available crystalline silicon photovoltaic solar cells have an efficiency of about 14-16 percent, but at least one major manufacture has a solar cell in development which can exceed 35 percent efficiency. Typical amorphous solar cells such as those commonly associated with flexible thin-films presently have an efficiency of approximately 5-6 percent, but thin-film solar cells are also in development which have greater efficiency. It would be possible to enjoy sunny days at least 75 percent of the time when the solar array would be located in Southern California, Arizona, or Nevada, thus providing about 294 days of productive power generation each year. In this regard, a solar reference cell such as one made or distributed by Kyocera Solar, Inc. of Scottsdale, Arizona can be used to measure the solar energy present in a given location. A solar array which can produce 4.6 kilowatt-hours given eight hours of exposure each day can generate approximately 1,352 kilowatt-hours each year, that is, given 294 productive days and a total of 2,262 productive hours. However, in desert climates such as the United Arab Emirates there could well be 360 productive days each year, thus 1,656 kilowatt-hours could be produced over 2,880 productive hours.

The artificial palm tree model consisting of a solar array can include a trunk approximately twenty feet high and have an overall height of about twenty-four feet. Further, each solar array can have a diameter of approximately sixteen feet, that is, given the span of two opposing artificial palm fronds each including stems one and one half feet long, blades six feet long, and a pole or trunk having a diameter of one foot. Given these dimensions, it can be advantageous that the artificial palm trees be separated by approximately thirty two feet on center in order to provide approximately sixteen feet of space between the ends of the artificial palm fronds in closest proximity, as this will avoid counterproductive shading out of adjacent artificial palm trees and solar arrays when the sun is inclined at less than 45 degrees with respect to the underlying ground surface. Accordingly, a single row of artificial palm trees and solar arrays spaced thirty two feet apart on both sides of a road can total approximately 330 units over a linear mile, and when a staggered double row is used on both sides of a highway the total can be approximately 660 units. Multiplying 1,352 kilowatt-hours per individual artificial palm tree and solar array per year given 294 productive days by 660 units along each mile of highway yields 892,320 kilowatt-hours per year. The average U.S. home consumes approximately 8,900 kilowatt-hours each year, thus each mile of highway so equipped could satisfy the power requirements of approximately 100 homes.

In the worst case scenario, given present distributor pricing for R15-1200 Powerfilm ® photovoltaic thin film, the cost of each installed model artificial palm tree solar array would be approximately $13,000. dollars. The cost of 660 solar arrays along a one mile stretch of highway would then be approximately $8,580,000. dollars. Assuming that the solar arrays would have a twenty year working life, then the annual cost for providing power to approximately 100 homes would be $429,000. dollars, or $4,290. dollars for each home. In the Pacific Northwest region of the United States, the cost of electricity is approximately 10 cents per kilowatt-hour, thus the annual cost of electricity for a home that consumes 8,900 kilowatt-hours is only $890. dollars. The relative cost of the photovoltaic solar energy system would then be approximately 4.8 times greater than that of the existing system in the Pacific Northwest.

However, the present distributor pricing for R15-1200 Powerfilm ® photovoltaic thin film is based upon a scale of production associated with the manufacture of only several thousand feet of material. If each artificial palm tree and solar array would use thirty two artificial palm fronds including a one foot by six foot long photovoltaic thin-film solar module, then 192 linear feet of such material would be required just to cover the top sides of the artificial palm fronds. The creation of 660 solar arrays over a mile of highway would require some 126,720 linear feet or approximately 24 miles of material. Accordingly, 100 miles of highway would require 2,400 miles of such material, and 1,000 miles of highway would require 24,000 miles of such material, that is, nearly equal to the circumference of the earth. Accordingly, the cost of producing photovoltaic thin film would decrease dramatically when manufactured on this scale.

### High Efficiency Model

For the purpose of providing a non-limiting simple example concerning the performance of such a solar array made with a thin film material having a relatively high efficiency in the range between 10.5-12.6% and having a cost of approximately $2.50 per watt, a model can be constructed using photovoltaic thin film made by Global Solar. A total of thirty-two artificial palm fronds can be arranged in four staggered layers with each layer including eight artificial palm fronds. The artificial palm fronds can have a stem approximately one and one half feet long. The working surface of the blade portion of each of the artificial palm fronds can measure approximately one and one half foot by nine feet, thus providing an area of 13.5 square feet. Accordingly, the total working surface area of the artificial palm tree model can consist of 431 square feet.

The resulting solar array can produce significant amounts of electrical power. In particular, each artificial palm frond including PowerFLEX® BIPV thin film made by Global Solar operates at approximately 17 volts and produces in the range between 5-6 amps. Multiplying the volts times the amps yields about 100 watt-hours of power, and then multiplying the rounded off 100 watt-hours by eight hours of sunlight yields 800 watt-hours per day for each artificial palm frond. Further, multiplying 800 watt-hours by thirty two fronds yields 25.6 kilowatt-hours per day for a single artificial palm tree consisting of a solar array. If and when there would be more than eight hours of sunlight, or when the artificial palm fronds would be larger in size, or when an additional thirty two PowerFLEX® BIPV units would be affixed to the bottom side of the artificial palm fronds as well, then the amount of power generated in a single day would be increased over and above the 25.6 kilowatt-hours per day.

A large portion of the Southwest region of the United States averages between six and seven hours of peak solar exposure or so-called “full sun hours” during the day, and the peak solar exposure in desert regions located closer to the equator is even greater. The sun's power or irradiance peaks at about 1,000 watts per square meter per hour. Most commercially available crystalline silicon photovoltaic solar cells have an efficiency of about 14-16 percent, but at least one major manufacture has a solar cell in development which can exceed 35 percent efficiency. Typical amorphous solar cells such as those commonly associated with flexible thin-films presently have an efficiency of approximately 5-6 percent as discussed in the relatively low efficiency model provided above, but other thin-film products are in development which have greater efficiency and some have already been commercialized such as Global Solar's PowerFLEX® BIPV thin film product. It would be possible to enjoy sunny days at least 75 percent of the time when the solar array would be located in Southern California, Arizona, or Nevada, thus providing about 294 days of productive power generation each year. In this regard, a solar reference cell such as one made or distributed by Kyocera Solar, Inc. of Scottsdale, Ariz. can be used to measure the solar energy present in a given location. A solar array which can produce 25.6 kilowatt-hours given eight hours of exposure each day can generate approximately 7,508 kilowatt-hours each year, that is, given 294 productive days and a total of 2,262 productive hours. However, in desert climates such as the United Arab Emirates there could well be 360 productive days each year, thus 9,216 kilowatt-hours could be produced over 2,880 productive hours.

Again, a single row of artificial palm trees and solar arrays spaced thirty two feet apart on both sides of a road can total approximately 330 units over a linear mile, and when a staggered double row is used on both sides of a highway the total can be approximately 660 units. Multiplying 2,262 kilowatt-hours per individual artificial palm tree and solar array per year given 294 productive days by 660 units along each mile of highway yields 1,357,200 kilowatt-hours per year. The average U.S. home consumes approximately 8,900 kilowatt-hours each year, thus each mile of highway so equipped could satisfy the power requirements of approximately 152 homes.

Given the present $2.50 cost per watt of the PowerFLEX® BIPV thin film product made by Global Solar, the cost of 660 solar arrays along a one mile stretch of highway would then be approximately $3,393,000. dollars. Assuming that the solar arrays would have a twenty year working life, the annual cost for providing power to approximately 152 homes would then be $22,322. dollars, or $1,116. dollars for each home. In the Pacific Northwest region of the United States, the cost of electricity is approximately 10 cents per kilowatt-hour, thus the annual cost of electricity for a home that consumes 8,900 kilowatt-hours is only $890. dollars. The relative cost of the photovoltaic solar energy system would then only be approximately $226. more than in the Pacific Northwest.

However, the present distributor pricing for the PowerFLEX® BIPV thin film product made by Global Solar is based upon a scale of production associated with the manufacture of only several thousand feet of material. If each artificial palm tree and solar array would use thirty two artificial palm fronds including a one and one half foot by nine foot long photovoltaic thin-film solar module, then 288 linear feet of such material would be required just to cover the top sides of the artificial palm fronds. The creation of 660 solar arrays over a mile of highway would require some 190,080 linear feet or approximately 36 miles of material. Accordingly, 100 miles of highway would require 3,600 miles of such material, and 1,000 miles of highway would require 36,000 miles of such material which is more than the circumference of the earth. Accordingly, the cost of producing photovoltaic thin film would decrease dramatically when manufactured on this scale.

In addition, as previously recited above, the article entitled “Solar-cell thinner than wavelengths of light hold huge power potential” which was published on the website: http://www.physorg.com/print204827475.html, as of Sep. 28, 2010, discusses the positive effects of providing a top layer including a patterned, roughened scattering layer which may have a green coloration. This technology can possibly result in more than a ten fold increase in the energy being absorbed by next generation solar cells due to their enhanced so-called “light trapping” capabilities.

Moreover, the direct and indirect costs associated with other alternative sources of electric power will most certainly not remain the same over the next 20 year time period, and so an investment in PV solar arrays which resemble palm trees that are both functional and aesthetically pleasing makes economic sense.

### Net Social Welfare Benefit

Once installed, the solar arrays can be easily maintained without substantial further expense. The artificial palm frond and solar module portion of the solar arrays can be recycled and renewed at the end of their expected twenty to forty year service life. If and when newer and more highly efficient artificial palm fronds and solar modules become available, then the older and less efficient components can be easily replaced without requiring significant changes to the network of solar arrays and solar power grid.

It is also important to recognize that the above calculations are unrealistically biased in favor of the status quo, as they are based on the assumption that the present cost of residential electric power in the Pacific Northwest will remain fixed at the present price of 9-10 cents per kilowatt-hour over the next forty years. Given the ever-increasing demand for energy this will certainly not be the case. Further, the Pacific Northwest is fortunate to enjoy hydroelectric power, whereas most of the United States and the rest of the world is dependent upon the burning of fossil fuels such as coal, oil, and gas in order to generate electric power. The cost of burning fossil fuels to produce energy is expected to increase dramatically over the next twenty to forty year time horizon. In fact, some experts believe that the world's non-renewable fossil fuel reserves will be largely exhausted during this period. In contrast, the cost of making and producing photovoltaic solar cells is expected to decrease dramatically.

Moreover, it should also be recognized that the investment costs associated with creating a network of solar cell arrays and solar power grid today will be partially offset by the effects of inflation over the next twenty to forty year period, as was the case with the dams and hydroelectric power plants built during the administration of President Franklin Roosevelt. Inflation is difficult to predict with great certainty, but since 1980 the value of the dollar has decreased such that it now enjoys slightly less than 50 percent of its former purchasing power. For example, it would have taken $2.18 in 2002 to match the purchasing power of one dollar in 1980. Accordingly, in 2020 and 2040 the investment made today in photovoltaic solar energy will appear as cost effective and prudent as the hydroelectric power initiatives of the 1930's and 1940's.

It can also be maintained that the net social welfare benefit associated with the use of clean and renewable solar power, as opposed to non-renewable fossil fuels such as petroleum, natural gas, or coal, also includes the cost savings and investment associated with the latter resources not being consumed. A barrel of oil saved is in some sense a barrel of oil earned, that is, it is a form of accumulated wealth. For example, when renewable solar energy is used the world has essentially saved the equivalent amount of energy associated with burning fossil fuels and saved it for higher value added use in the future. When viewed from a time horizon of a hundred or thousand years, fossil fuels such as petroleum are worth far more in the ground, than they are today when simply burned-up as fuel.

It is possible to roughly estimate the net social welfare benefit associated with using clean and renewable solar power as opposed to non-renewable fossil fuels such as petroleum, natural gas, or coal. In 2003, the cost of a barrel containing 42 gallons of crude oil was approximately $30.00 dollars, but this represented only about 42 percent of the cost of a petroleum end product as delivered to a consumer, thus the actual cost to a household was approximately $ 71.42 dollars. Only eight years later in 2011, the cost of a barrel containing 42 gallons of crude oil is approximately $80.00 dollars, and this represents about 42 percent of the cost of a petroleum end product as delivered to a consumer, thus the actual cost to a household is approximately $190.40 dollars. One barrel of crude oil is equal to 5,800,000 Btu, and one gallon of gasoline is equal to 124,000 Btu, whereas one gallon of diesel fuel is equal to 139,000 Btu. One kilowatt-hour of electricity is equal to 3,412 Btu. Accordingly, one barrel of crude oil is equal to approximately 1,670 kilowatt-hours. The annual energy consumption associated with electric power and heating for the average home in the United States is approximately 8,900 kilowatt-hours. However, the energy consumption of the average middle class home in the United States is greater. The inventor presently owns a 2,450 square foot home in a suburb of Portland, Oreg. In 2002, about $567. dollars was paid for electric power, and about $815. dollars was paid for natural gas for a total of approximately $1,381. dollars. Converting that sum into kilowatt-hours given a present cost of 10 cents per kilowatt-hour yields a total annual consumption of 13,810 kilowatt-hours.

Furthermore, the annual fuel consumption and energy cost associated with the use of an automobile in the United States should also be considered. An automobile that uses gasoline having a fuel efficiency of 20 miles to the gallon which is driven 12,000 miles each year will consume approximately 600 gallons of gasoline. In 2003, gasoline fuel cost $1.75 per gallon, and those 600 gallons cost $1,050. dollars, and would fill about 14.25 barrels having a capacity of 42 gallons. Only eight years later in 2011, gasoline fuels costs $3.75 per gallon, and those 600 gallons cost $2,250. dollars. Almost everything contained in a barrel of crude oil is refined and used to make various petroleum products, but most refineries only produce about 19 gallons of gasoline from a 42 gallon barrel of crude oil. Accordingly, about 1,326 gallons of crude oil are refined to produce those 600 gallons of gasoline, and such would fill about 31.6 barrels having a capacity of 42 gallons. One gallon of gasoline is equal to 124,000 Btu, and thus 600 gallons of gasoline equals 74,400,000 Btu. One kilowatt-hour of electricity is equal to 3,412 Btu. Accordingly, those 600 gallons of gasoline equate to about 21,805 kilowatt-hours, thus over twice what the average home in the United States consumes for basic electric power and heating. Moreover, the burning of fossil fuels also results in additional direct and indirect costs associated with pollution and global warming. While substantial, these indirect costs can be difficult to estimate.

It is clear that United States needs to switch from automobiles which burn gasoline and diesel fuel to electric and hybrid vehicles as soon as possible. In this regard, it should be recognized that merely switching from automobiles that burn gasoline and diesel fuel to electric and hybrid vehicles which must be charged by electric power plants that burn fossil fuels would not provide a viable long term solution to the world's energy and pollution problems. At this time, and for the foreseeable future, the only clean and renewable form of electric power comes from the sun. That energy and power needs to made available in and alongside our nation's public transportation right of ways including railways, roads and highways. Accordingly, the creation of a network of solar arrays and power grid along roads and highways will not only provide electrical energy and power for residential and commercial use, but also support and make viable the widespread use of electric and hybrid transportation vehicles.

While the above detailed description of the invention contains many specificities, these should not be construed as limitations on the scope of the invention, but rather as exemplifications of several preferred embodiments thereof. Although the present invention has been described with reference to preferred embodiments, workers skilled in the art will recognize that changes may be made in form and detail without departing from the spirit and scope of the invention. Accordingly, the scope of the invention should be determined not by the embodiments discussed or illustrated, but by the appended claims and their legal equivalents.

What is claimed is:

1. A solar array, comprising:
a structure configured to resemble a tree comprising;
a trunk portion; and
a plurality of solar modules coupled with said trunk portion; and
a wireless transmission device adapted to transmit energy coupled with said structure.

2. The solar array according to claim 1, wherein said solar array is configured to resemble a tree selected from the group of trees consisting of deciduous trees, evergreen trees, and palm trees.

3. The solar array according to claim 1, wherein said trunk comprises a support pole and an interior compartment, and each of said solar modules are configured to resemble a palm frond including a stem portion and a blade portion, said stem portion extending from said trunk portion, said blade portion including at least one solar cell having a working surface area for capturing sunlight and for providing an electrical energy output, wiring coupled to said plurality of solar modules for conducting said electrical energy output, and at least one mechanical fastener for securing said solar array in an upright position.

4. The solar array according to claim 1, wherein each of said plurality of solar modules comprise a green coloration.

5. The solar array according to claim 1, wherein said wireless transmission device is configured to transmit energy within a portion of the electromagnetic spectrum.

6. The solar array according to claim 5, wherein said wireless transmission device is configured to transmit energy selected from the group consisting of: gamma ray energy, x-ray energy, ultraviolet light energy, visible light energy, infrared energy, microwave energy, radio frequency energy, radar energy, electric energy, television signal energy, and telephone signal energy.

7. The solar array according to claim 1, further comprising:
a transmission device configured to wirelessly transmit electrical energy to a receiver device coupled with a transportation vehicle; wherein said transmission device is coupled with said structure by at least one wire.

8. The solar array according to claim 7, wherein said transmission device is substantially planar and is located on a substantially horizontal surface capable of supporting a transportation vehicle.

9. The solar array according to claim 8, wherein:
said receiver device is generally planar;
said transportation vehicle has a lower surface; and
said receiver device is located on said lower surface.

10. The solar array according to claim 7, wherein said transmission device is located on a vertical support surface.

11. The solar array according to claim 10, wherein said receiver device is located on at least one of the front, rear, and side surfaces of the transportation vehicle.

12. The solar array according to claim 1, further including:
at least one repeater device electrically coupled to said structure adapted to extend the range of wireless transmission of energy.

13. The solar array according to claim 1, further comprising:
a monitoring and controlling device coupled with said structure by at least one wire;
wherein said monitoring and controlling device comprises a visual display.

14. The solar array according to claim 1, further comprising:
a monitoring and controlling device, wherein said monitoring and controlling device comprises;
a visual display; and
a communications device for wirelessly transmitting signals to and from said structure.

15. The solar array according to claim 14, wherein said monitoring and controlling device comprises an electronic device selected from the group of electronic devices consisting of monitors, controllers, computers and cell phones.

16. The solar array according to claim 1, wherein:
said energy comprises electrical energy; and
said structure further comprises a battery for storing the electrical energy.

17. The solar array according to claim 1, further comprising at least one electronic component selected from the group of: electronic components consisting of adaptors, AC disconnects, amplifiers, batteries, battery cables, battery controllers, battery status meters, bias voltage supply devices, breakers, capacitors, central processing units, chips, circuit breakers, coils, tesla coils, computers, conduits, connectors, controllers, charge controllers, micro-controllers, control panels, digital and panel controls, converters, combiners, DC disconnects, DC-DC power optimizers, diodes, drivers, gate drivers, full bridge drivers, extension cords, filters, fuses, generators, grid tie power centers, ground fault switches, h-bridge power stages, inductors, integrated circuits, inverters, micro-inverters, junction boxes, lights, meters, metal oxide semiconductors, output current and voltage sense amplifiers, off grid power centers, power supplies, power optimizer chipsets switching power supplies, quasi-resonant flyback devices, rectified full wave Sine-to-Sine bridges, regulators, RF receivers, repeaters, resistors, sensors, sensing and detection devices, software, shot reactors, static var compensators, surge protectors, switches, temperature sensors, thyristors, transformers, transistors, bi-polar junction transistors, voltage regulators, wiring, wireless RF communication devices, wireless transmitters, wireless receivers, and wireless repeaters.

18. The solar array according to claim 1, wherein the solar array is coupled with an electric power grid.

19. A network of solar arrays, comprising:
a plurality of solar arrays;
wherein each of said solar arrays comprises;
a structure configured to resemble a tree, comprising;
a trunk portion; and
a plurality of solar modules coupled with said trunk portion; and
a wireless transmission device adapted to transmit energy coupled with said structure.

20. The network of claim 19, wherein said plurality of solar arrays is coupled with at least one recharging station adapted to provide electrical energy to an electrical power storage device coupled with a transportation vehicle.

21. The solar array of claim 1, wherein said solar array is located in a parking area and adapted to recharge an electric power storage device of an electric transportation vehicle.

22. The network of claim 19, wherein said plurality of solar arrays is located along a path of travel of a transportation vehicle and said network of solar arrays is adapted to provide electric power to said transportation vehicle while it is in motion.

23. A solar array comprising a structure configured to resemble a tree comprising a trunk portion and a plurality of solar modules, said solar array comprising means for wireless transmission of electric power.

24. The solar array according to claim 23, wherein said means for wireless transmission of electric power comprises electromagnetic inductance.

25. The solar array according to claim 23, wherein said means for wireless transmission of electric power comprises electromagnetic radiation comprising radio frequency.

26. A solar array resembling natural foliage, wherein the improvement comprises an antenna.

27. A solar array resembling natural foliage, wherein the improvement comprises a communications device, said communications device selected from the group consisting of antennas, receivers, transmitters, relays, and repeaters.

28. A solar array resembling natural foliage, wherein the improvement comprises an electrolyser device adapted to provide hydrogen fuel.

29. A solar array resembling natural foliage, wherein the improvement comprises an electrolyser device adapted to provide pure water.
